(19) United States
(12) Patent Application Publication
(10) Pub. No.: US 2025/0349665 A1
(43) Pub. Date: Nov. 13, 2025

(54) PACKAGE AND MANUFACTURING METHOD THEREOF

(71) Applicant: TAIWAN SEMICONDUCTOR MANUFACTURING COMPANY, LTD., Hsinchu (TW)

(72) Inventors: Yi-Huan LIAO, Hsinchu County (TW); Ping-Yin HSIEH, Hsinchu City (TW); Chih-Hao CHEN, Taipei city (TW); Li-Hui CHENG, New Taipei City (TW)

(73) Assignee: TAIWAN SEMICONDUCTOR MANUFACTURING COMPANY, LTD., Hsinchu (TW)

(21) Appl. No.: 18/657,578

(22) Filed: May 7, 2024

(51) Int. Cl. H01L 23/42; H01L 23/00; H01L 23/10; H01L 23/367

(52) U.S. Cl. CPC H01L 23/42; H01L 23/10; H01L 23/367; H01L 24/29; H01L 24/32; H01L 24/83; H01L 2224/29109; H01L 2224/29111; H01L 2224/29139; H01L 2224/29147; H01L 2224/32245; H01L 2224/83424; H01L 2224/83447; H01L 2224/8346

(57) ABSTRACT

A method includes bonding a package component to a substrate; forming a molding compound laterally surrounding the package component; forming a thermal interface material (TIM) layer over the package component; forming a first adhesive layer over the molding compound, the first adhesive layer laterally surrounding the TIM layer; attaching a bottom surface of a lid to the TIM layer. The lid has a first trench recessed from the bottom surface thereof, a footprint of the first trench surrounds a footprint of the package component on the substrate, and a footprint of the first adhesive layer surrounds a footprint of the first trench on the substrate.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-18G and 19-21B illustrate schematic views of intermediate stages in the formation of a package in accordance with some embodiments of the present disclosure.

FIGS. 18H and 18I illustrate schematic top views of packages corresponding to FIG. 18G in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present disclosure are applicable to compute-in-memory, processing-in-memory, processing-using-memory, near-memory-compute, near-data processing, near-memory processing, in-storage processing, GPU accelerator, TPU accelerator, In-memory computing, in-memory-processing, compute near memory, and/or processing near memory.

For large chip-on-wafer-on-substrate (CoWoS) packages featuring entirely flat surfaces above the substrate. Such packages may encounter a risk of lid delamination when a flat lid is applied. Additionally, after attaching the heat sink, irregular voids may have been discovered within the package. In some embodiments, the voids can compromise the mechanical bond between the metallic thermal interface material (TIM) and the lid, reducing the structural integrity of the package and making it more susceptible to delamination or failure during thermal cycling.

Therefore, the present disclosure in various embodiments provides a flat lid featuring a trench (or cavity) therein over a package, which in turn mitigates the delamination and prevents the formation of irregular voids associated with the use of metallic TIM between the lid and the package. The additional trench within the lid can provide the space for constructing an adhesive (ADH) dam structure. This adhesive dam structure can include more than two layers of adhesive around the chip-on-wafer (CoW) die, which in turn controls package warpage and inhibits the bleeding/overflowing of the metallic TIM between the lid and the package. Additionally, the top layer of the adhesive dam with opening can avert potential distortion of the dam itself.

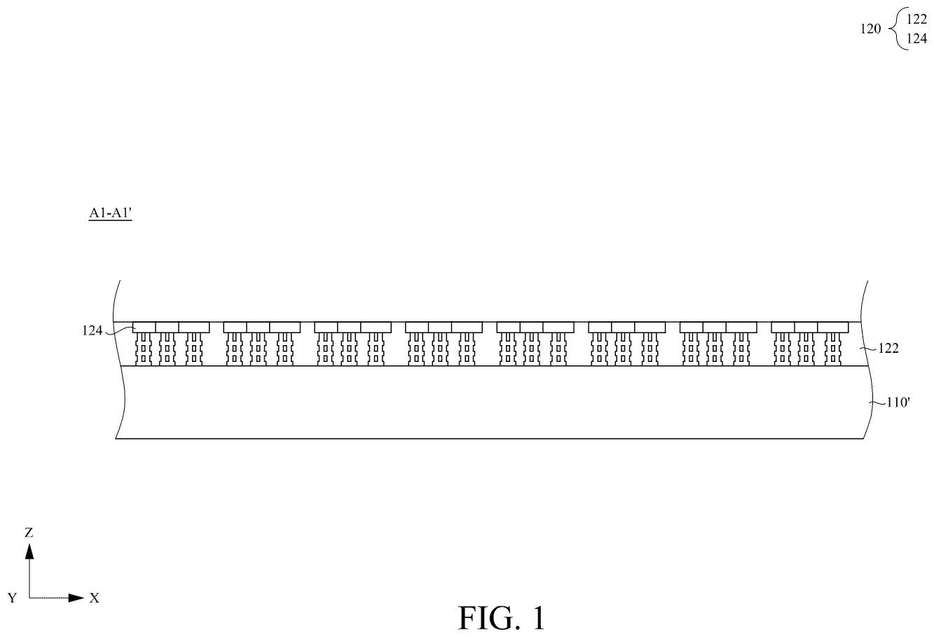

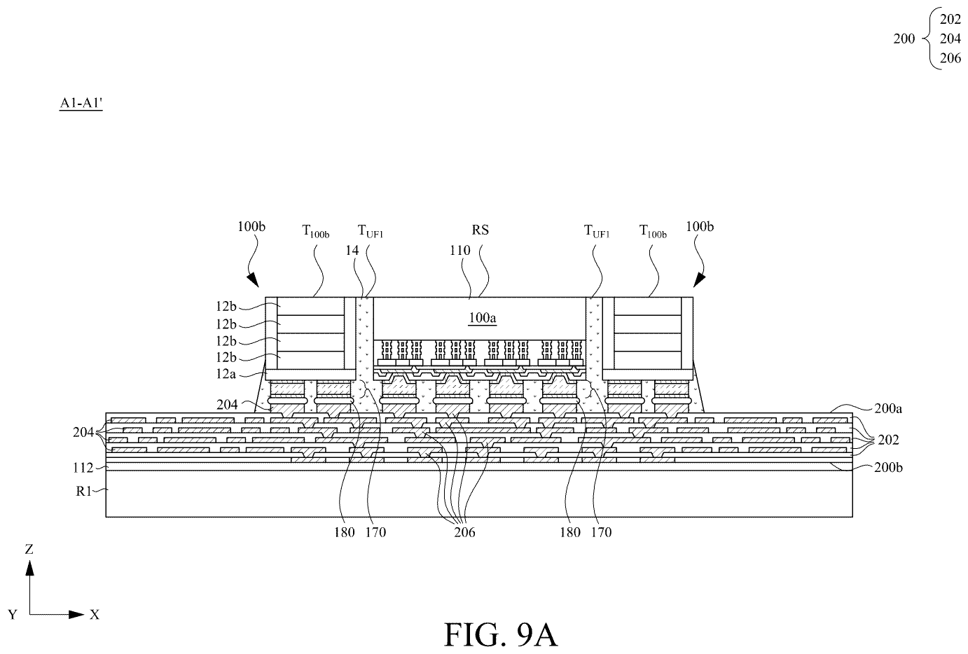

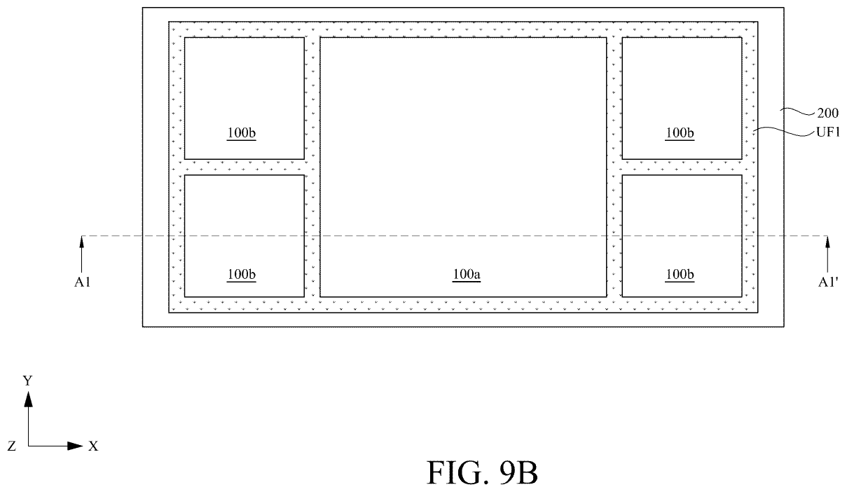

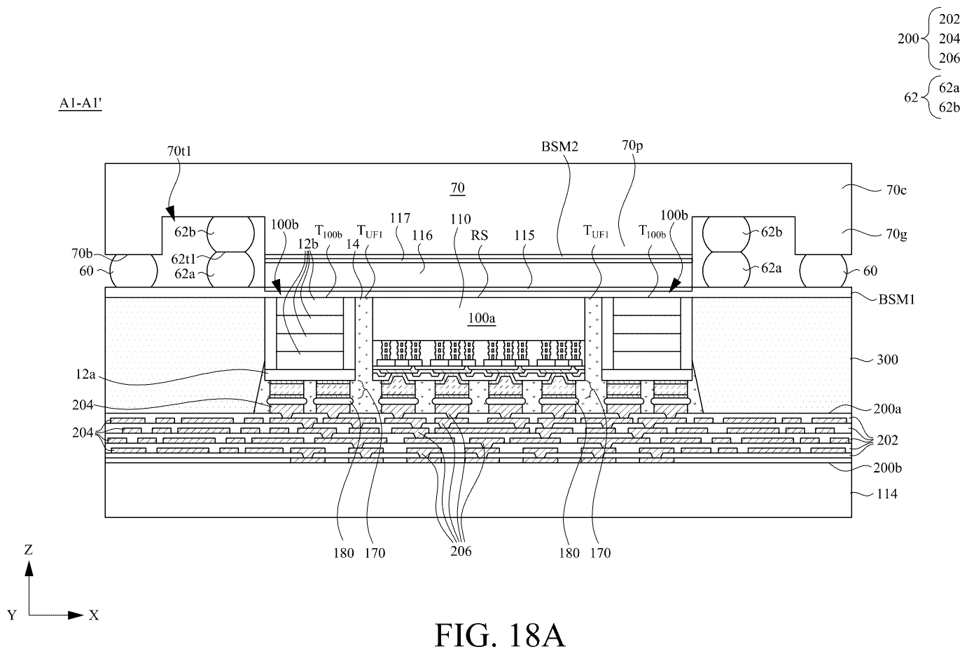

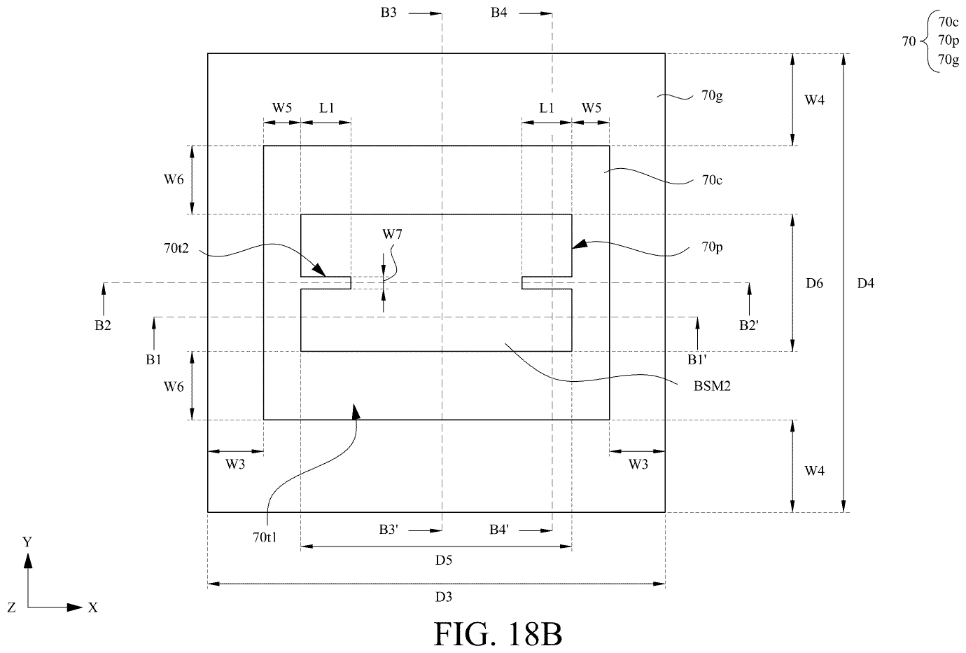

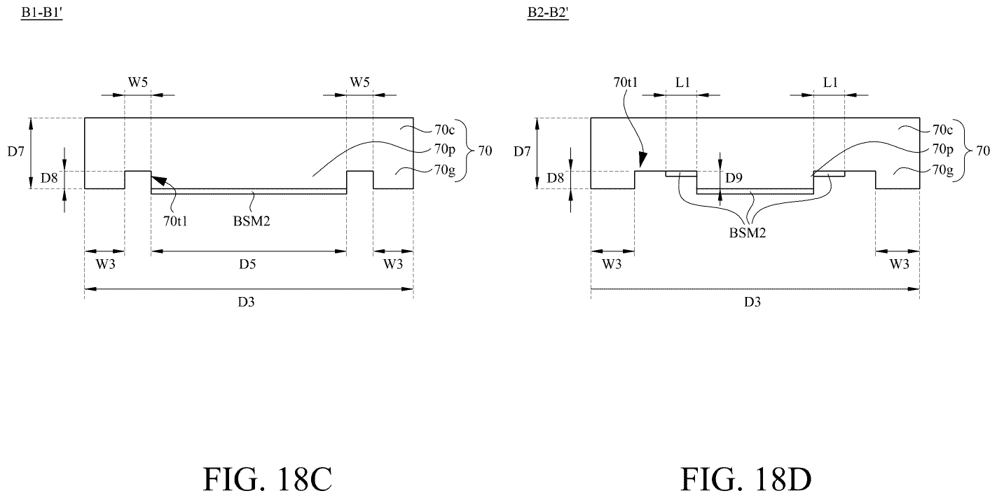

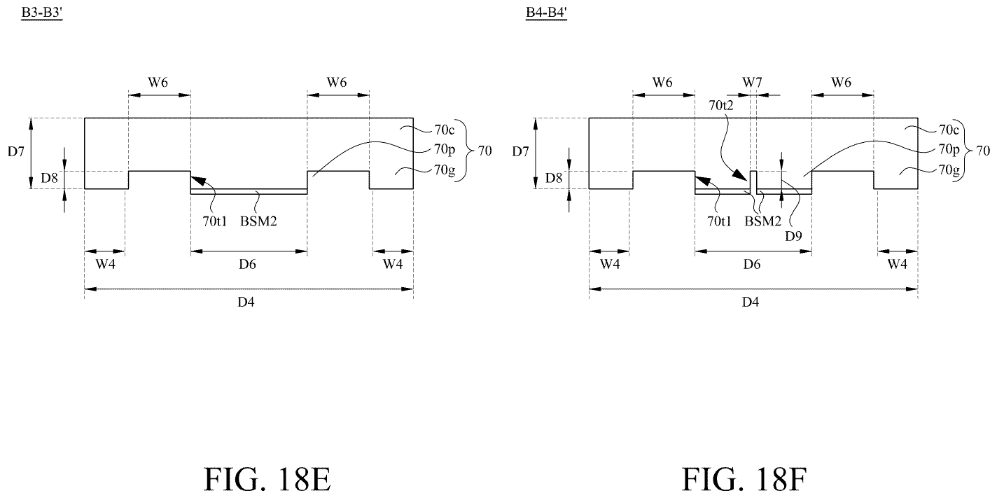

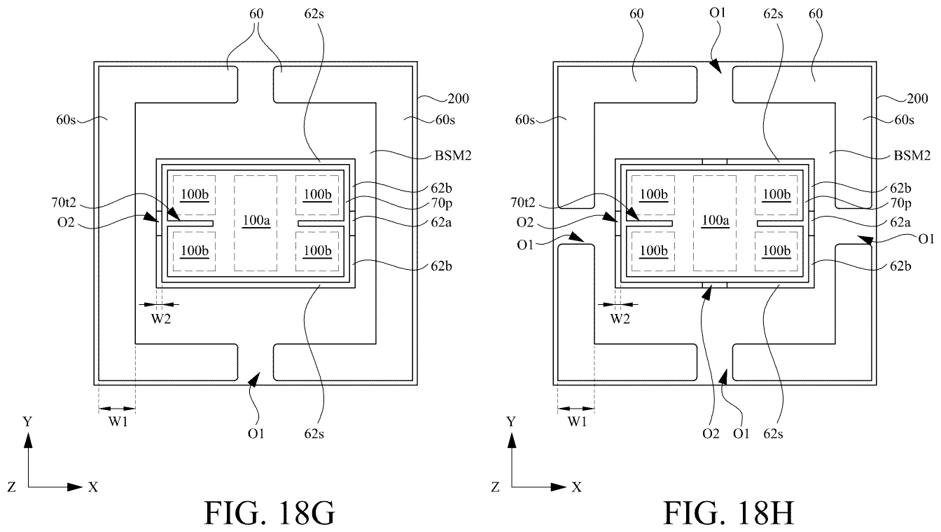

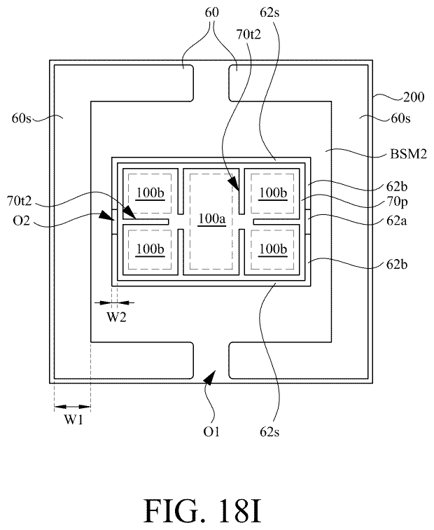

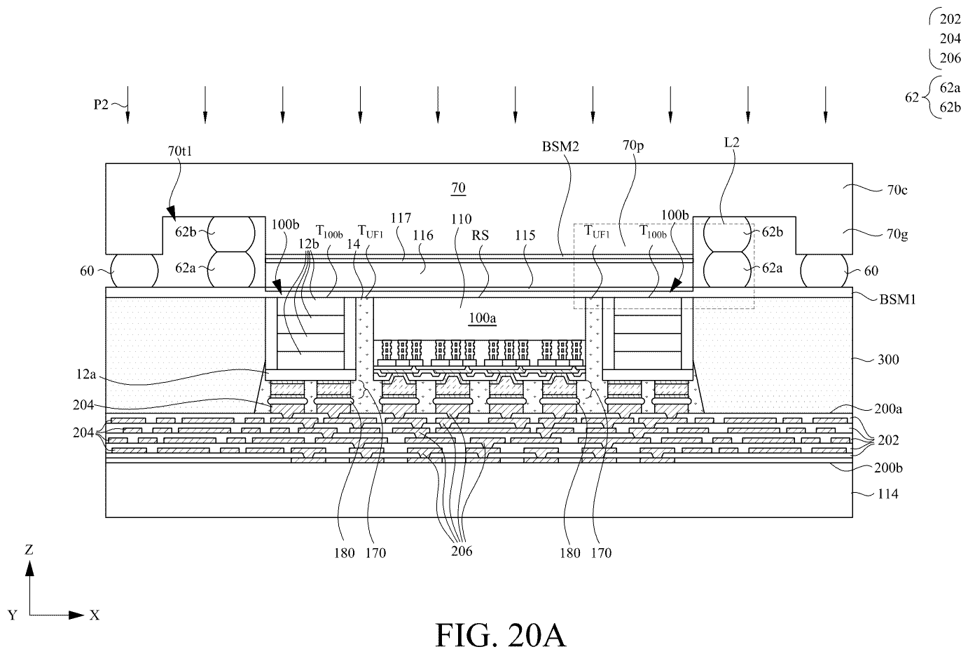

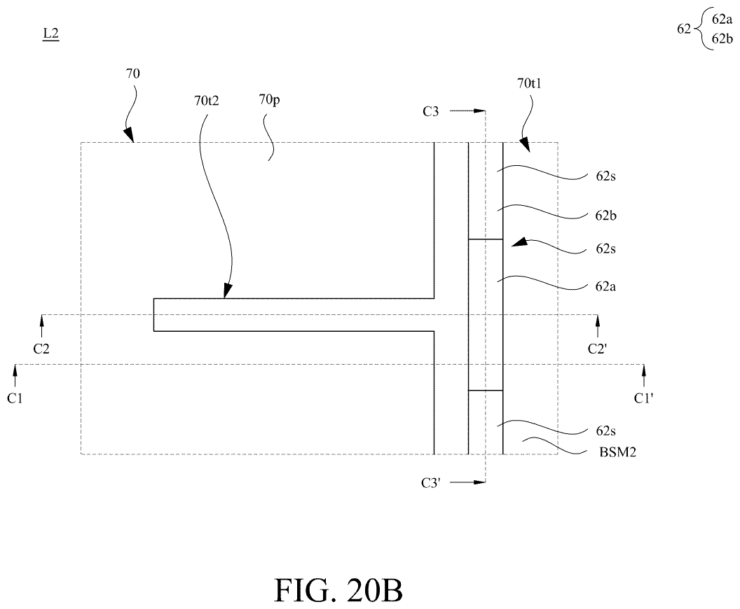

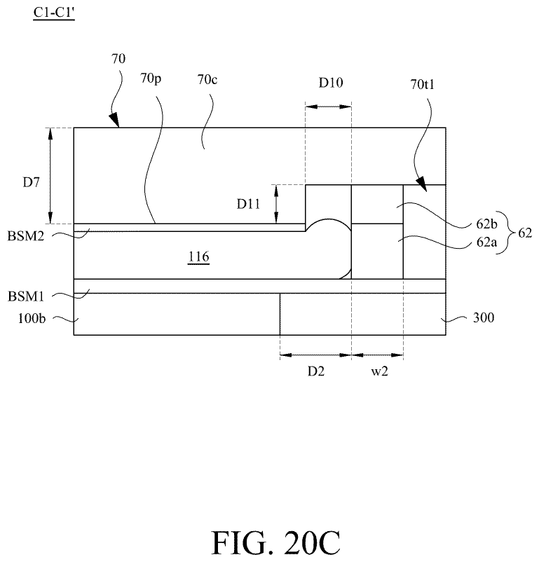

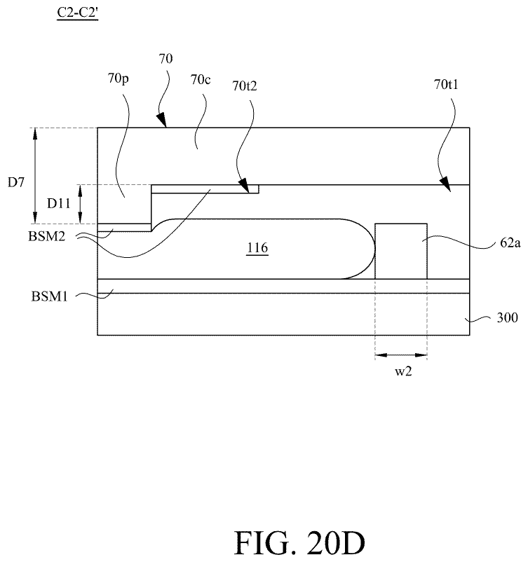

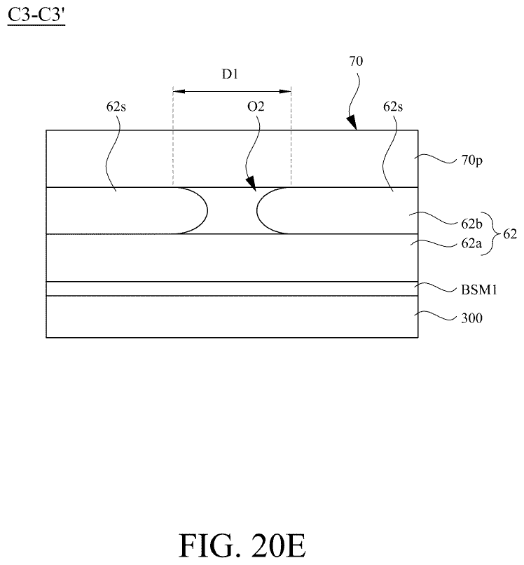

Reference is made to FIGS. 1-20B and 20E-21B. FIGS. 1-18G and 19-21B illustrate schematic views of intermediate stages in the formation of a package structure in accordance with some embodiments of the present disclosure. Specifically, FIGS. 1-9A, 10-17A, 18A, 19, 20A, 21A, and 21B illustrate schematic cross-sectional views of the package 10 obtained from reference cross-section A1-A1′ in FIGS. 9B in accordance with some embodiments of the present disclosure. FIGS. 9B, 17B, and 18G illustrate schematic top views of the package structure corresponding to FIGS. 9A, 17A, and 18A, respectively, in accordance with some embodiments of the present disclosure. For simplicity and clarity of illustration, some elements are omitted in the simplified top view of FIGS. 9B, 17B, and 18G, and these elements might not be located in the same plane. FIG. 18B illustrates a schematic top view of a lid structure 70 in accordance with some embodiments of the present disclosure. FIGS. 18C, 18D, 18E, and 18F illustrate cross-sectional views of the lid structure 70 obtained from reference cross-sections B1-B1′, B2-B2′, B3-B3′, B4-B4′ in FIG. 18B in accordance with some embodiments of the present disclosure. FIG. 20B illustrates a schematic local enlarged view of a region L2 in FIG. 20A in accordance with some embodiments of the present disclosure. FIGS. 20C, 20D, and 20E illustrate cross-sectional views of the package structure obtained from reference cross-sections C1-C1′, C2-C2′, and C3-C3′ in FIG. 20B in accordance with some embodiments of the present disclosure. It is understood that additional operations can be provided before, during, and after the processes shown by FIGS. 1-18G and 19-21B, and some of the operations described below can be replaced or eliminated, for additional embodiments of the method. The order of the operations/processes may be interchangeable.

Reference is made to FIG. 1. A semiconductor wafer 110′ can be provided. In some embodiments, the semiconductor wafer 110′ can be made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the semiconductor wafer 110′ can have active components (e.g., transistors or the like) and passive components (e.g., resistors, capacitors, inductors, or the like) formed therein.

In some embodiments, an interconnection structure 120 can be formed on the semiconductor wafer 110′. In some embodiments, the interconnection structure 120 can include an inter-dielectric layer 122 and a plurality of patterned conductive layers 124. For simplicity, the inter-dielectric layer 122 can be illustrated as a bulky layer in FIG. 1, but it should be understood that the inter-dielectric layer 122 may be constituted by multiple dielectric layers. The patterned conductive layers 124 and the dielectric layers of the inter-dielectric layer 122 can be stacked alternately. In some embodiments, two vertically adjacent patterned conductive layers 124 can be electrically connected to each other through conductive vias sandwiched therebetween.

In some embodiments, the material of the inter-dielectric layer 122 can include polyimide, epoxy resin, acrylic resin, phenol resin, benzocyclobutene (BCB), polybenzoxazole (PBO), or other suitable polymer-based dielectric materials. The inter-dielectric layer 122 may be formed by suitable fabrication techniques, such as spin-on coating, chemical vapor deposition (CVD), plasma-enhanced chemical vapor deposition (PECVD), or the like. In some embodiments, the material of the patterned conductive layers 124 can include aluminum, titanium, copper, nickel, tungsten, and/or alloys thereof. The patterned conductive layers 124 may be formed by electroplating, deposition, and/or photolithography and etching. It should be noted that the number of the patterned conductive layers 124 and the dielectric layers in the inter-dielectric layer 122 shown in FIG. 1A is merely an exemplary illustration, and the disclosure is not limited. In some alternative embodiments, the number of the patterned conductive layers 124 and the number of the dielectric layers in the inter-dielectric layer 122 may be adjusted depending on the routing requirements.

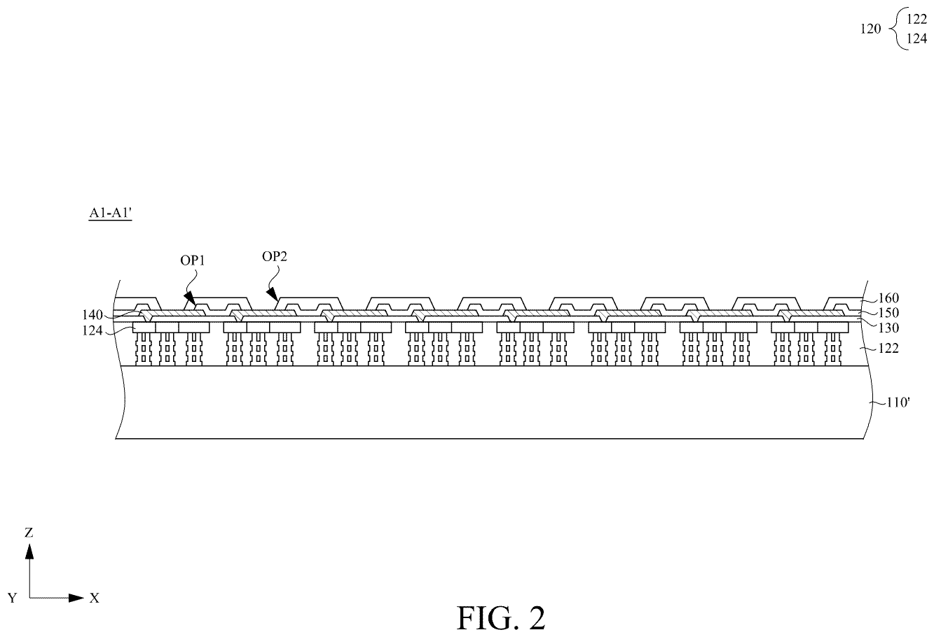

Reference is made to FIG. 2. A dielectric layer 130 can be formed over the interconnection structure 120. In some embodiments, the material of the dielectric layer 130 can include polyimide, epoxy resin, acrylic resin, phenol resin, BCB, PBO, or any other suitable polymer-based dielectric material. The dielectric layer 130 may be formed by suitable fabrication techniques, such as spin-on coating, CVD, PECVD, or the like. In some embodiments, a plurality of openings can be formed in the dielectric layer 130 to expose portions of the topmost patterned conductive layer 124. After the openings are formed, a plurality of conductive pads 140 can be formed over the dielectric layer 130. For example, the conductive pads 140 can be formed over the semiconductor wafer 110′ and the interconnection structure 120, such that the interconnection structure 120 can be located between the semiconductor wafer 110′ and the conductive pads 140. In some embodiments, the locations of the conductive pads 140 can correspond to the locations of the openings of the dielectric layer 130. For example, the conductive pads 140 can extend into the openings of the dielectric layer 130 to render electrical connection between the conductive pads 140 and portions of the interconnection structure 120 (i.e., the patterned conductive layer 124). In some embodiments, the conductive pads 140 can be aluminum pads, copper pads, or other suitable metal pads. The number and the shape of the conductive pads 140 may be selected based on demand.

After the conductive pads 140 are distributed over the dielectric layer 130, a passivation layer 150 and a post-passivation layer 160 can be sequentially formed over the dielectric layer 130 and the conductive pads 140. In some embodiments, the passivation layer 150 can have a plurality of contact openings OP1 which partially exposes the conductive pads 140. In some embodiments, the passivation layer 150 can be a silicon oxide layer, a silicon nitride layer, a silicon oxy-nitride layer, or a dielectric layer formed by other suitable dielectric materials. As illustrated in FIG. 2, the post-passivation layer 160 can cover the passivation layer 150 and have a plurality of contact openings OP2. The conductive pads 140 can be partially exposed by the contact openings OP2 of the post-passivation layer 160. In some embodiments, the post-passivation layer 160 can be a polyimide layer, a PBO layer, or a dielectric layer formed by other suitable polymers. It should be noted that the post-passivation layer 160 may be optional in some embodiments.

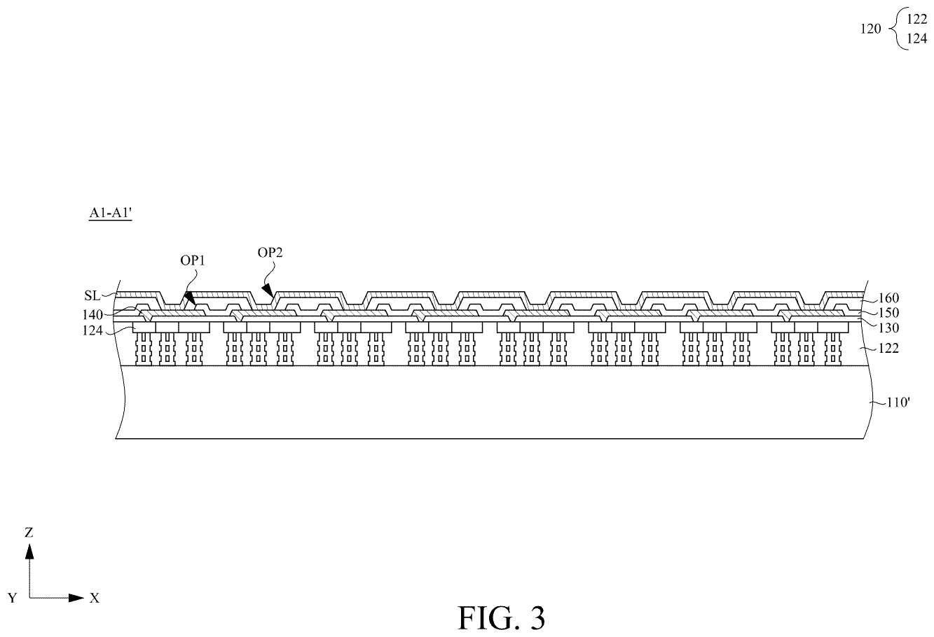

Reference is made to FIG. 3. After forming the post-passivation layer 160, a seed layer SL can be conformally formed on the post-passivation layer 160. For example, at least a portion of the seed layer SL extends into the contact openings OP2 of the passivation layer 160 to be in physical with the conductive pads 140. The seed layer SL may be formed through a sputtering process, a physical vapor deposition (PVD) process, or the like. In some embodiments, the seed layer SL can be constituted by two sub-layers (not shown). In such embodiments, the first sub-layer may include titanium, titanium nitride, tantalum, tantalum nitride, other suitable materials, or a combination thereof, and the second sub-layer may include copper, copper alloys, or other suitable choice of materials.

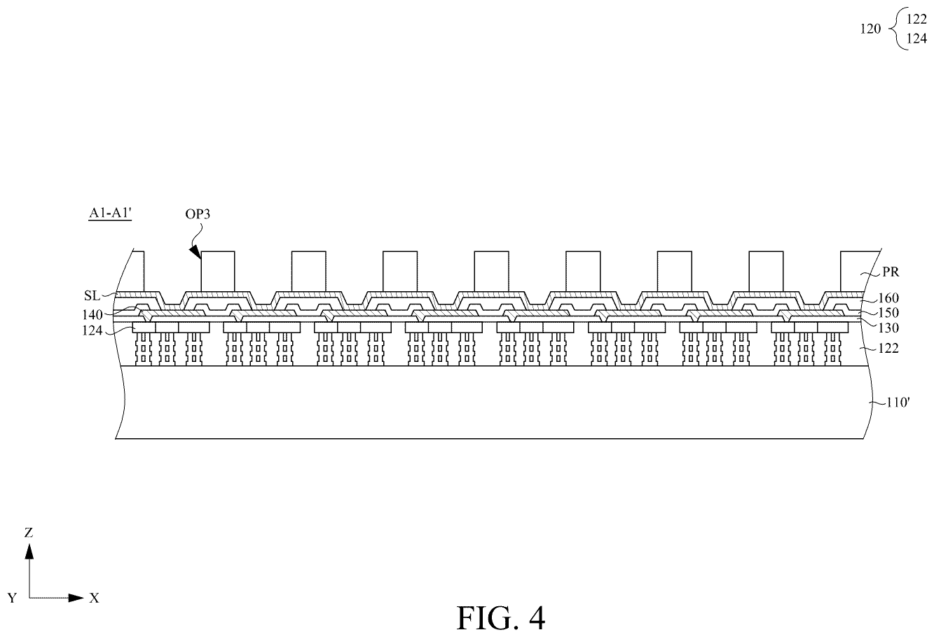

Reference is made to FIG. 4. A patterned photoresist layer PR can be formed over the seed layer SL. In some embodiments, the patterned photoresist layer PR can be made of a photosensitive material. In some embodiments, the patterned photoresist layer PR can have a plurality of openings OP3 partially exposing the seed layer SL above the contact pads 140. For example, the openings OP3 can expose the seed layer SL located directly above the contact pads 140.

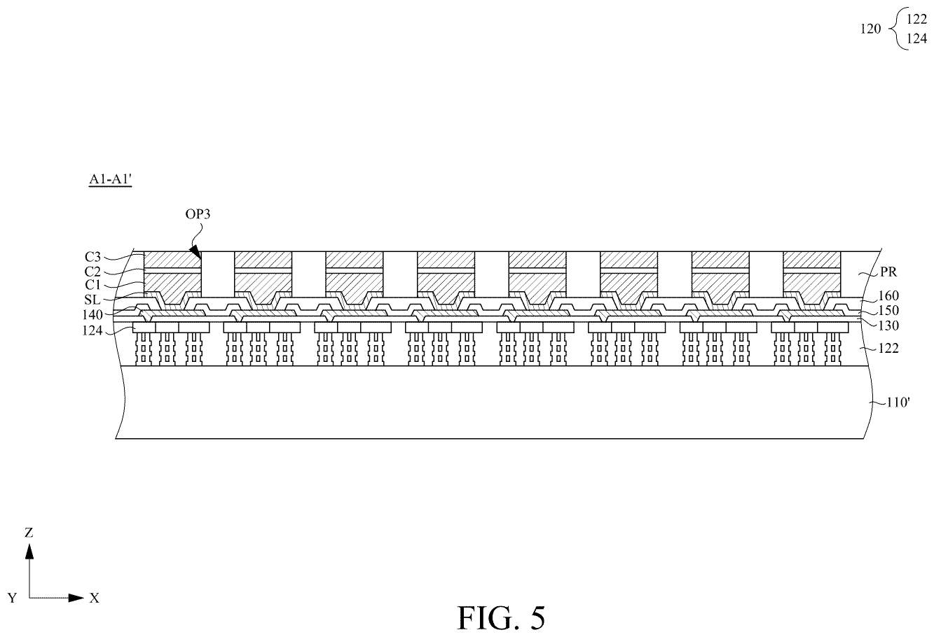

Reference is made to FIG. 5. A first conductive layer C1, a second conductive layer C2, and a third conductive layer C3 can be sequentially deposited onto the exposed seed layer SL. For example, the first conductive layer C1, the second conductive layer C2, and the third conductive layer C3 can be filled into the openings OP3 of the patterned photoresist layer PR. In some embodiments, the first conductive layer C1, the second conductive layer C2, and the third conductive layer C3 can be formed through the same technique. However, the disclosure is not limited thereto. In some alternative embodiments, the first conductive layer C1, the second conductive layer C2, and the third conductive layer C3 may be formed by different techniques. In some embodiments, the first conductive layer C1, the second conductive layer C2, and the third conductive layer C3 can be formed through a plating process. The plating process is, for example, an electro-plating process, an electroless-plating process, an immersion plating process, or the like. In some embodiments, the materials of the first conductive layer C1, the second conductive layer C2, and the third conductive layer C3 can be different. For example, the first conductive layer C1 can be made of aluminum, titanium, copper, tungsten, and/or alloys thereof; the second conductive layer C2 can be made of nickel; and the third conductive layer C3 can be made of solder. In some embodiments, a solder flux (not shown) may be applied onto the third conductive layer C3 for better adhesion. In some embodiments, the thickness of the first conductive layer C1 can be greater than the thickness of the second conductive layer C2 and the thickness of the third conductive layer C3. And, the thickness of third conductive layer C3 can be greater than the thickness of the second conductive layer C2.

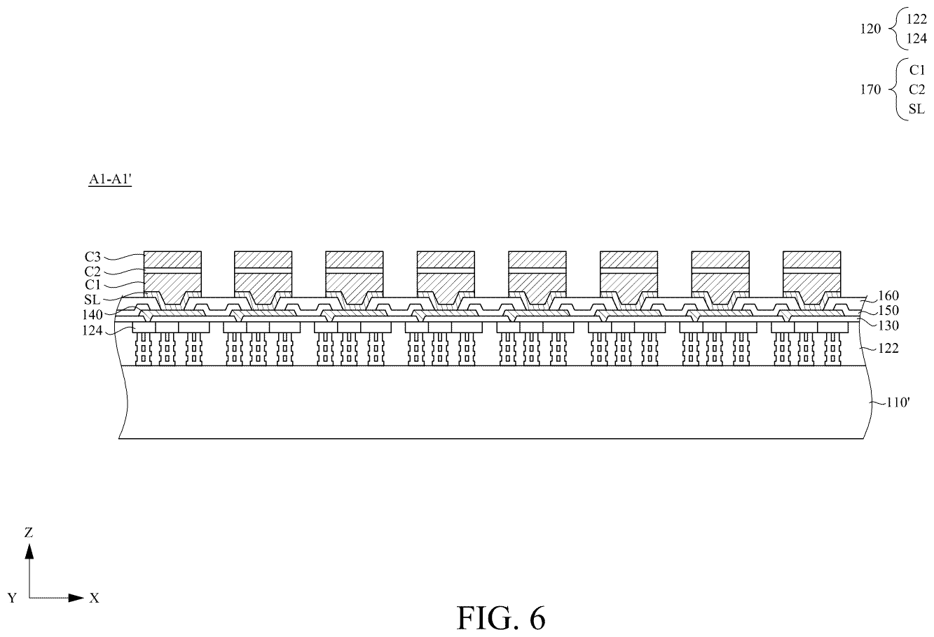

Reference is made to FIGS. 5 and 6. The patterned photoresist layer PR can be removed. The patterned photoresist layer PR may be removed through an etching process, a stripping process, an ashing process, a combination thereof, or the like. Thereafter, by using the first conductive layer C1, the second conductive layer C2, and the third conductive layer C3 as hard masks, the seed layer SL that is uncovered by the first conductive layer C1, the second conductive layer C2, and the third conductive layer C3 can be removed. In some embodiments, portions of the seed layer SL can be removed through an etching process. After removal of portions of the seed layer SL, the remaining seed layer SL can be located directly underneath the first conductive layer C1. That is to say, the seed layer SL can be sandwiched between the contact pads 140 and the first conductive layer C1. In some embodiments, the remaining seed layer SL, the first conductive layer C1, and the second conductive layer C2 are collectively referred to as conductive posts 170.

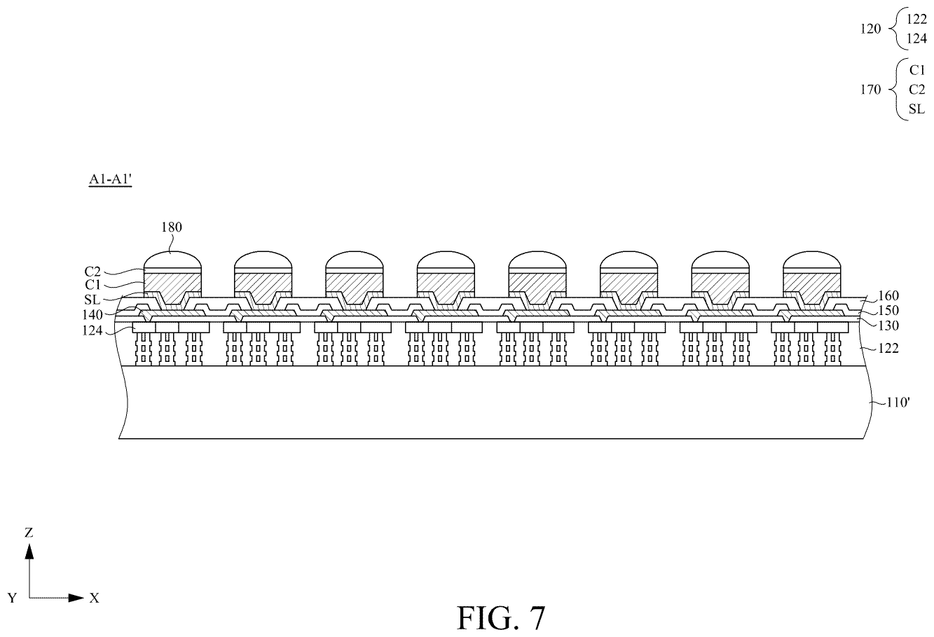

Reference is made to FIGS. 6 and 7. A reflow process can be performed on the third conductive layer C3 to transform the third conducive layer C3 into conductive terminals 180. That is to say, the conductive terminals 180 can be formed on the conductive posts 170. In some embodiments, the third conductive layer C3 can be reshaped during the reflow process to form hemispherical conductive terminals 180.

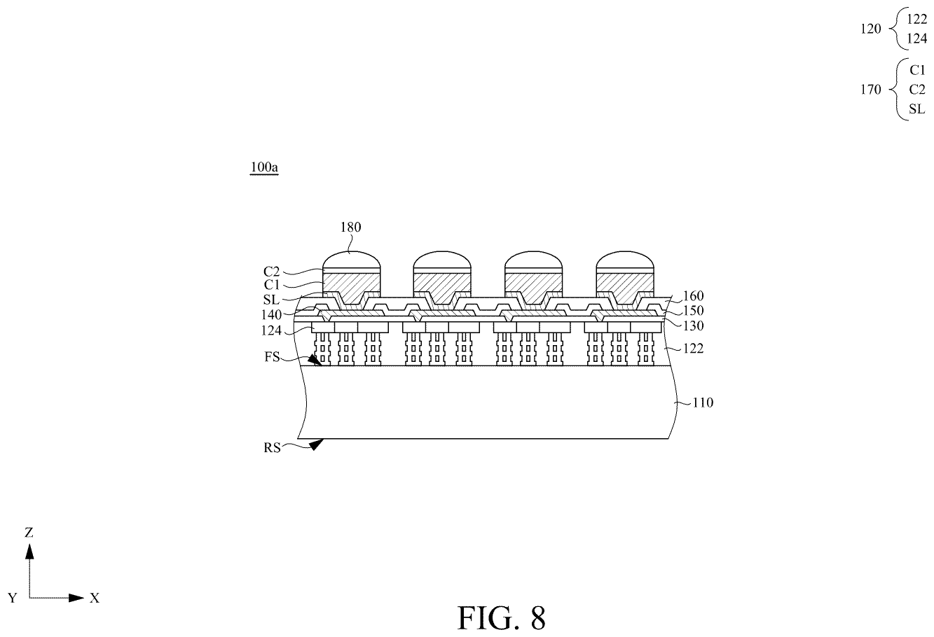

Reference is made to FIGS. 7 and 8. The structure illustrated in FIG. 7 can be singulated to render a plurality of semiconductor dies 100a shown in FIG. 8. In some embodiments, the singulation process typically can involve dicing with a rotation blade and/or a laser beam. In other words, the singulation process can include a laser cutting process, a mechanical cutting process, a laser grooving process, other suitable processes, or a combination thereof. For example, a laser grooving process may be performed on the structure illustrated in FIG. 7 to form trenches (not shown) in the said structure. Thereafter, a mechanical cutting process may be performed on the locations of the trenches to cut through the said structure, so as to divide the semiconductor wafer 110′ into semiconductor substrates 110 and to obtain the semiconductor dies 100a.

Reference is made to FIG. 8. The semiconductor die 100a can include the semiconductor substrate 110, the interconnection structure 120, the dielectric layer 130, the conductive pads 140, the passivation layer 150, the post-passivation layer 160, the conductive posts 170, and the conductive terminals 180. In some embodiments, the semiconductor substrate 110 can have a front surface FS and a rear surface RS opposite to the front surface FS. The interconnection structure 120 can be disposed on the front surface FS of the semiconductor substrate 110. The dielectric layer 130, the conductive pads 140, the passivation layer 150, and the post-passivation layer 160 can be sequentially disposed over the interconnection structure 120. The conductive posts 170 can be disposed over the post-passivation layer 160 and are electrically connected to the conductive pads 140. The conductive terminals 180 can be disposed on the conductive posts 170. Further, as shown in FIG. 8, although four conductive posts 170 and four conductive terminals 180 are presented in the semiconductor die 100a for illustrative purposes, those skilled in the art can understand that the number of the conductive posts 170 and the number of the conductive terminals 180 may be more than or less than what is depicted in FIG. 1H, and may be designated based on demand and/or design layout.

In some embodiments, the semiconductor die 100a can be capable of performing logic functions. For example, the semiconductor die 100a may include or be a Central Process Unit (CPU) die, a Graphic Process Unit (GPU) die, a Field-Programmable Gate Array (FPGA), system-on-a-chip (SoC), or the like. In some embodiments, the semiconductor die 100a may be utilized in a package structure. For example, the semiconductor die 100a may be assembled with other components to form a package structure. The manufacturing process of the package structure utilizing the semiconductor die 100a will be described below.

Reference is made to FIGS. 9A and 9B. An interposer 200 can be provided. In some embodiments, the interposer 200 can be disposed on (or attached to) a carrier R1 through a release film 112. The carrier R1 can be provided to support the package structure thereon. In some embodiments, the carrier R1 and the release film 112 may not be used. The carrier R1, when used, may be a glass carrier, an organic carrier, or the like. The release film 112 can be formed on carrier R1 for attaching package components to the carrier R1. The release film 112 may be formed of a polymer-based material (e.g., a light-to-heat-conversion (LTHC) material), which may be an epoxy-based thermal-release material.

In some embodiments, the interposer 200 can include a plurality of dielectric layers 202, a plurality of conductive pattern layers 204, and a plurality of conductive vias 206. In some embodiments, the dielectric layers 202 and the conductive pattern layers 204 can be stacked alternately. In some embodiments, the conductive vias 206 can be embedded in the dielectric layers 202. In some embodiments, the conductive pattern layers 204 can be interconnected with one another through the conductive vias 206. For example, the conductive vias 206 can penetrate through the dielectric layers 202 to connect the conductive pattern layers 204. In some embodiments, each conductive pattern layer 204 can include a plurality of conductive patterns serving as redistribution wirings. In some embodiments, the conductive patterns of the outermost conductive pattern layers 204 (i.e., the topmost conductive pattern layer 204 and the bottommost conductive pattern layer 204) shown in FIG. 9A can be referred to as under-ball metallurgy (UBM) patterns for ball mount. In some embodiments, the conductive pattern layers 204 can transmit signals horizontally and the conductive vias 206 can transmit signals vertically.

In some embodiments, the material of the dielectric layers 202 can includes polyimide, epoxy resin, acrylic resin, phenolic resin, BCB, PBO, or any other suitable polymer-based dielectric material. In some embodiments, the dielectric layers 202 can include resin mixed with filler. The dielectric layers 202 may be formed by suitable fabrication techniques, such as film lamination, spin-on coating, CVD, PECVD, or the like. In some embodiments, the material of the conductive pattern layers 204 and the conductive vias 206 can include aluminum, titanium, copper, nickel, tungsten, or alloys thereof. The conductive pattern layers 204 and the conductive vias 206 may be formed by electroplating, deposition, and/or photolithography and etching. In some embodiments, the conductive pattern layers 204 and the underlying conductive vias 206 can be formed simultaneously. It should be noted that the number of the dielectric layers 202, the number of the conductive pattern layers 204, and the number of the conductive vias 206 illustrated in FIG. 9A are merely for illustrative purposes, and the disclosure is not limited thereto. In some alternative embodiments, fewer or more layers of the dielectric layers 202, the conductive pattern layers 204, and the conductive vias 206 may be formed depending on the circuit design.

In some embodiments, the interposer 200 can have a first surface 200a and a second surface 200b opposite to the first surface 200a. The topmost conductive pattern layer 204 can be exposed at the first surface 200a and the bottommost conductive pattern layer 204 can be exposed at the second surface 200b. In some embodiments, the interposer 200 can be a silicon-free substrate. In some embodiments, the interposer 200 can be referred to an “organic interposer”. The organic interposer can be beneficial to reduce the total process cost of the package structure since the organic interposer can be a low-cost interposer. In some embodiments, the critical dimension (e.g., line width or space width) of the organic interposer can be closer to the critical dimension of at least one of the semiconductor chips. In some embodiments, the interposer 200 can be interchangeable referred to as a substrate.

Continue referring to FIGS. 9A and 9B, at least one semiconductor die 100a shown in FIG. 8 and at least one semiconductor die 100b are bonded to the first surface 200a of the interposer 200. As shown in FIGS. 9A and 9B, two semiconductor dies 100b each can be disposed aside and around one semiconductor die 100a. However, the disclosure is not limited thereto. Those skilled in the art can understand that the number of the semiconductor die 100a may be more than what is depicted in FIGS. 9A and 9B, the number of the semiconductor die 100b may be more than or less than what is depicted in FIGS. 9A and 9B, and may be designated based on demand and/or design layout. In some alternative embodiments, when more than one semiconductor die 100a and more than two semiconductor dies 100b can be bonded to the interposer 200, the semiconductor dies 100b can be disposed around each of the semiconductor dies 100a. In some embodiments, more than one identical semiconductor die 100a can be bonded to the interposer 200. However, the disclosure is not limited thereto. In some alternative embodiments, different semiconductor dies 100a may be bonded to the interposer 200.

Further, as shown in FIGS. 9A and 9B, the semiconductor die 100a and the semiconductor dies 100b can be bonded to the first surface 200a of the interposer 200 through flip chip bonding. That is, each of the semiconductor die 100a and the semiconductor dies 100b can be upside down, so that the conductive terminals 180 of each of the semiconductor die 100a and the semiconductor dies 100b can face toward the interposer 200. In detail, as shown in FIG. 9A, the semiconductor die 100a and the semiconductor dies 100b can be attached to the interposer 200 through the conductive terminals 180. For example, the conductive terminals 180 of the semiconductor die 100a and the semiconductor dies 100b can be in physical contact with the topmost conductive pattern layer 204 exposed at the first surface 200a of the interposer 200 to render electrical connection between the semiconductor die 100a and the interposer 200 and electrical connection between the semiconductor dies 100b and the interposer 200. In some embodiments, after the conductive terminals 180 are attached to the topmost conductive pattern layer 204 of the interposer 200, a reflow process can be performed to reshape the conductive terminals 180. Further, as shown in FIG. 9A, although two conductive posts 170 and two conductive terminals 180 are presented in the semiconductor die 100b for illustrative purposes, those skilled in the art can understand that the number of the conductive posts 170 and the number of the conductive terminals 180 of the semiconductor die 100b may be more than or less than what is depicted in FIG. 9A, and may be designated based on demand and/or design layout.

In some embodiments, the semiconductor die 100b can be a memory die. For example, as shown in FIGS. 9A and 9B, the semiconductor die 100b may include or be a high bandwidth memory (HBM) die or a hybrid memory cube (HMC) die. In such embodiments, as shown in FIGS. 9A and 9B, the semiconductor die 100b can include a logic die 12a, a stack of memory dies disposed on the logic die 12a, and an encapsulant 14 laterally encapsulates the stack of memory dies, wherein the stack of memory dies includes a plurality of memory dies 12b. The number of the memory dies 12b may be less than or more than what is depicted in FIG. 9A, and may be designated based on the demand and/or design layout; the disclosure is not specifically limited thereto. In some embodiments, the stack of memory dies can be bonded to the logic die 12a, and the memory dies 12b can be bonded to each other. In some embodiments, the electrical connections between the logic die 12a and the memory dies 12b can be established by through-substrate vias and micro-bump bonding. However, the disclosure is not limited thereto. In some alternative embodiments, the electrical connections between the logic die 12a and the memory dies 12b can be established by through-substrate vias and metal-to-metal bonding of the hybrid bonding. In some alternative embodiments, the electrical connections between the logic die 12a and the memory dies 12b can be established by redistribution structures and through insulator vias. In some embodiments, the material of the encapsulant 14 can include a molding compound, a molding underfill, a resin (such as epoxy resin, phenolic resin), or the like. In some alternative embodiments, the material of the encapsulant 14 can include silicon oxide (SiOx, where x>0), silicon oxynitride (SiOxNy, where x>0 and y>0), silicon nitride (SiNx, where x>0), or other suitable dielectric material. In some embodiments, the material of the encapsulant 14 may further include filler particles (e.g., silica, clay or the like). In some embodiments, the encapsulant 14 can be formed through an over-molding process. For example, the over-molding process can be a compression molding process. In some alternative embodiments, the encapsulant 14 can be formed through a film deposition process. For example, the film deposition process includes CVD, High-Density Plasma Chemical Vapor Deposition (HDPCVD), PECVD, atomic layer deposition (ALD), or combinations thereof. In some embodiments, as shown in FIG. 9A, a top surface T_{100b} of the semiconductor die 100b can be substantially coplanar with the rear surface RS of the semiconductor substrate 110 in the semiconductor die 100a.

Furthermore, as shown in FIGS. 9A and 9B, the semiconductor die 100b can be presented as a HBM die or a HMC die, but it is merely an example illustration. In some alternative embodiments, the semiconductor die 100b may be other types of memory die, such as dynamic random-access memory (DRAM) die, static random-access memory (SRAM) die or resistive random-access memory (RRAM) die. And, as shown in FIG. 9A, two identical semiconductor dies 100b can be bonded to the interposer 200. However, the disclosure is not limited thereto. In some alternative embodiments, different semiconductor dies 100b may be bonded to the interposer 200.

In some embodiments, an underfill layer UF1 can be formed over the interposer 200 to encapsulate the semiconductor die 100a and the semiconductor dies 100b. As shown in FIG. 9A and 9B, the underfill layer UF1 wraps around the conductive posts 170 and the conductive terminals 180 of the semiconductor die 100a and the semiconductor dies 100b, and the topmost conductive pattern layer 204 exposed at the first surface 200a and bonded with the conductive terminals 180 of the semiconductor die 100a and the semiconductor dies 100b. Owing to the underfill layer UF1, a bonding strength between the semiconductor die 100a and the interposer 200 and a bonding strength between the semiconductor die 100b and the interposer 200 are enhanced, thereby improving the reliability of the package structure. In some embodiments, as shown in FIG. 9A, the underfill layer UF1 can be formed to fill the spaces between the semiconductor die 100a and the semiconductor dies 100b. In detail, as shown in FIGS. 9A and 9B, the underfill layer UF1 can completely cover inner sidewalls of the semiconductor die 100a and the semiconductor dies 100b, and partially covers outer sidewalls of the semiconductor die 100a and the semiconductor dies 100b. For example, as shown in FIG. 9A, the portions of the underfill layer UF1 located at the spaces between the semiconductor die 100a and the semiconductor dies 100b have a top surface TUFI that can be substantially coplanar with the rear surface RS of the semiconductor substrate 110 in the semiconductor die 100a. However, the disclosure is not limited thereto. In some alternative embodiments, the top surface TUFI of the underfill layer UF1 may be located below or above the rear surface RS of the semiconductor substrate 110. In some embodiments, the underfill layer UF1 can be formed by a capillary flow process after the semiconductor die 100a and the semiconductor dies 100b are attached the interposer 200. That is to say, the underfill layer UF1 can be drawn by capillary action to flow through the spaces between the semiconductor die 100a and the semiconductor dies 100b, the space between the semiconductor die 100a and the interposer 200, and the spaces between the semiconductor dies 100b and the interposer 200. In some embodiments, the material of the underfill layer UF1 can be an insulating material and includes a resin (e.g., epoxy resin), a filler material, a stress release agent (SRA), an adhesion promoter, other material, or a combination thereof. In some embodiments, the underfill layer UF1 can be optional.

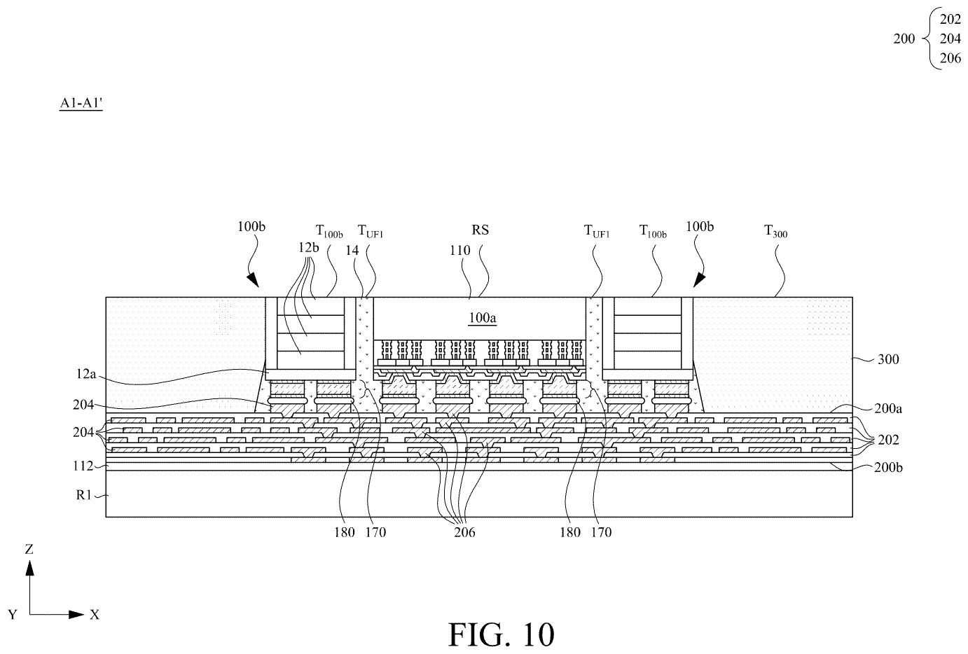

Reference is made to FIG. 10. An encapsulant 300 can be formed over the interposer 200 to encapsulate the semiconductor die 100a, the semiconductor dies 100b, and the underfill layer UF1. For example, the encapsulant 300 can laterally encapsulate the semiconductor die 100a, the semiconductor dies 100b, and the underfill layer UF1. As illustrated in FIG. 10, a top surface T₃₀₀ of the encapsulant 300 can be substantially coplanar with the rear surface RS of the semiconductor substrate 110, the top surfaces T_{100b} of the semiconductor dies 100b and the top surface TUFI of the underfill layer UF1. That is to say, the encapsulant 300 exposes the semiconductor substrate 110 of the semiconductor die 100a and the memory die 12 b of the semiconductor die 100b. In some embodiments, the encapsulant 300 can be a molding compound, a molding underfill, a resin (such as epoxy resin, phenolic resin), or the like. In some alternative embodiments, the material of the encapsulant 14 include silicon oxide (SiOx, where x>0), silicon oxynitride (SiOxNy, where x>0 and y>0), silicon nitride (SiNx, where x>0), or other suitable dielectric material. In some embodiments, the encapsulant 300 includes fillers. The fillers may be particles made of silica, aluminum dioxide, or the like. In some embodiments, the encapsulant 300 can be formed by a molding process, an injection process, a film deposition process, a combination thereof, or the like. The molding process includes, for example, a transfer molding process, a compression molding process, or the like. The film deposition process includes, for example, CVD, HDPCVD, PECVD, ALD, or combinations thereof.

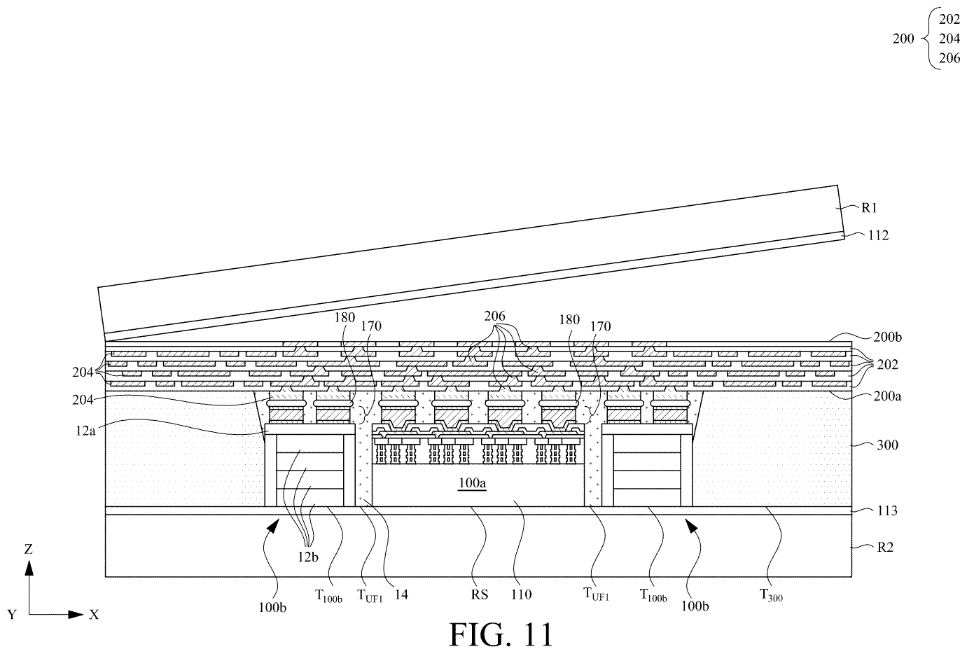

Reference is made to FIG. 11. The top surface T₃₀₀ of the encapsulant 300, the rear surface RS of the semiconductor substrate 110, the top surfaces T_{100b} of the semiconductor dies 100b, and the top surface TUFI of the underfill layer UF1 can be disposed on (or attached to) a carrier R2 through a release film 113. That is, each of the semiconductor die 100a and the semiconductor dies 100b can be upside down, so that the interposer 200 can face away from the carrier R2. The carrier R2 can be provided to support the package structure thereon. In some embodiments, the carrier R2 and the release film 113 may not be used. The carrier R2, when used, may be a glass carrier, an organic carrier, or the like. The release film 113 can be formed on carrier R2 for attaching package components to the carrier R2. The release film 113 may be formed of a polymer-based material (e.g., a light-to-heat-conversion (LTHC) material), which may be an epoxy-based thermal-release material.

Subsequently, in accordance with some embodiments, the carrier R1 can be de-bonded from the interposer 200. In accordance with some embodiments, a light beam such as a laser beam is projected on the release film 112, and the release film 112 can be de-composed under the heat of the light beam. The interposer 200 and the overlying structures are thus released from the carrier R1.

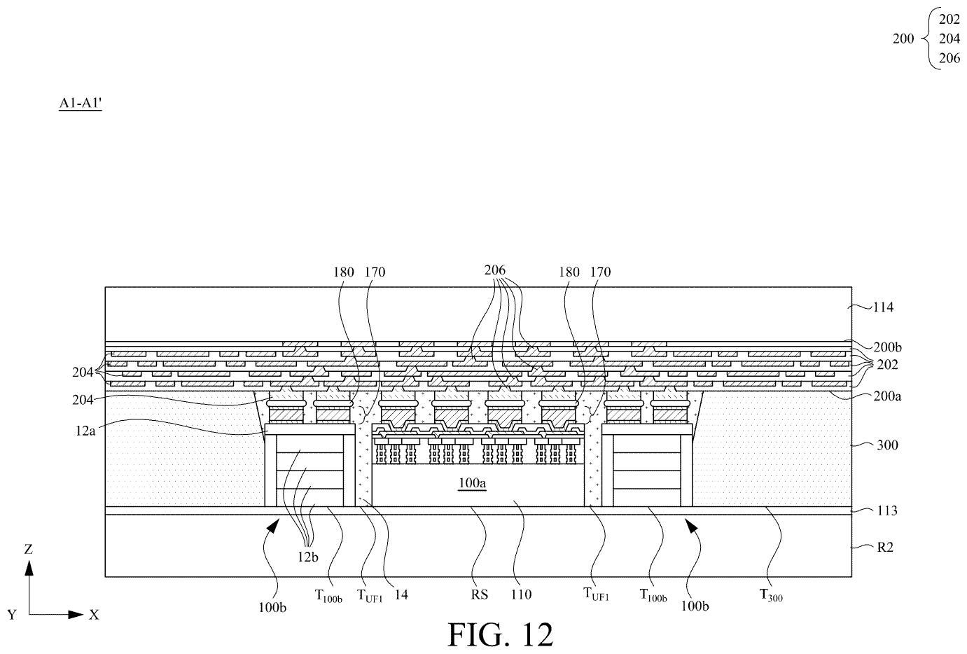

Reference is made to FIG. 12. A substrate 114 can be provided. The substrate 114 can be can be made of a suitable elemental semiconductor, such as crystalline silicon, diamond, or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. In some embodiments, the substrate 114 can have active devices (e.g., transistors or the like) and/or integrated passive devices (IPDs) (e.g., resistors, capacitors, inductors, or the like) formed therein. In some embodiments, the substrate 114 can be bonded to the second surface 200b of the interposer 200 through flip chip bonding. That is, each of the devices in the substrate 114 can be upside down, so that the conductive terminals (not shown) of the substrate can face toward the interposer 200. Therefore, the substrate can be attached to the interposer 200 through the conductive terminals thereon. For example, the conductive terminals of the substrate 114 can be in physical contact with the conductive pattern layer 204 exposed at the second surface 200b of the interposer 200 to render electrical connection between the devices in the substrate 114 and the interposer 200.

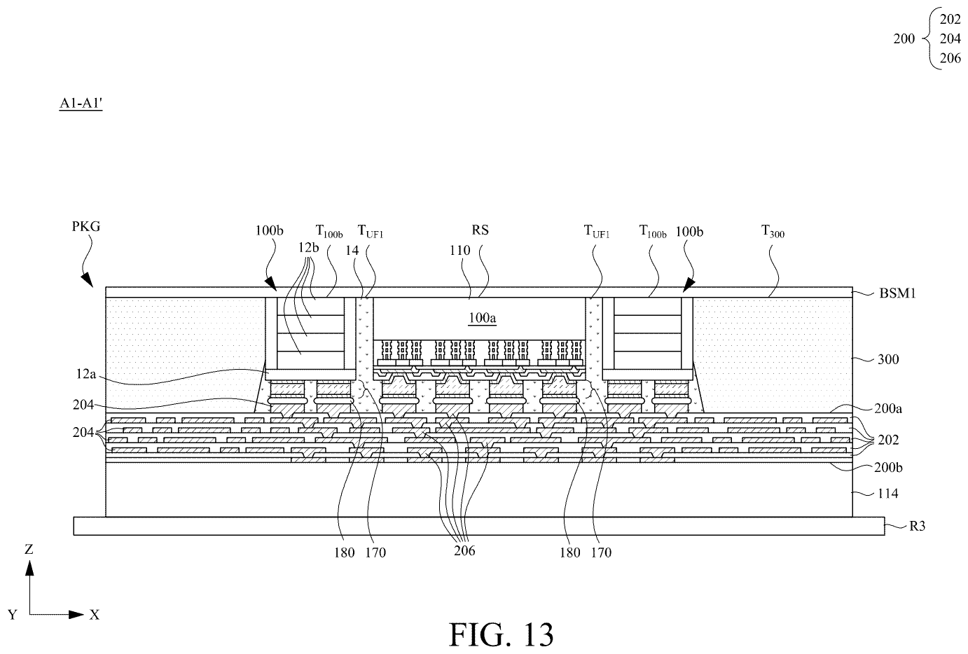

Reference is made to FIG. 13. The carrier R2 on the structure illustrated in FIG. 12 can be de-bonded from the encapsulant 300, the semiconductor substrate 110, the semiconductor dies 100b, and the underfill layer UF1. In accordance with some embodiments, a light beam such as a laser beam is projected on release film 113, and release film 113 is de-composed under the heat of the light beam. Subsequently, the structure illustrated in FIG. 12 can be placed on the carrier R3. The carrier R3 may include a frame and a tape being held tightly by the frame. In some embodiments, the carrier R3 can help to provide support such that a conductive layer BSM1 can be formed on the semiconductor die 100a, the semiconductor dies 100b and the encapsulant 300. However, the disclosure is not limited to. In some alternative embodiments, the carrier R3 may be a glass carrier, so as to perform a carrier bond process on the substrate 114.

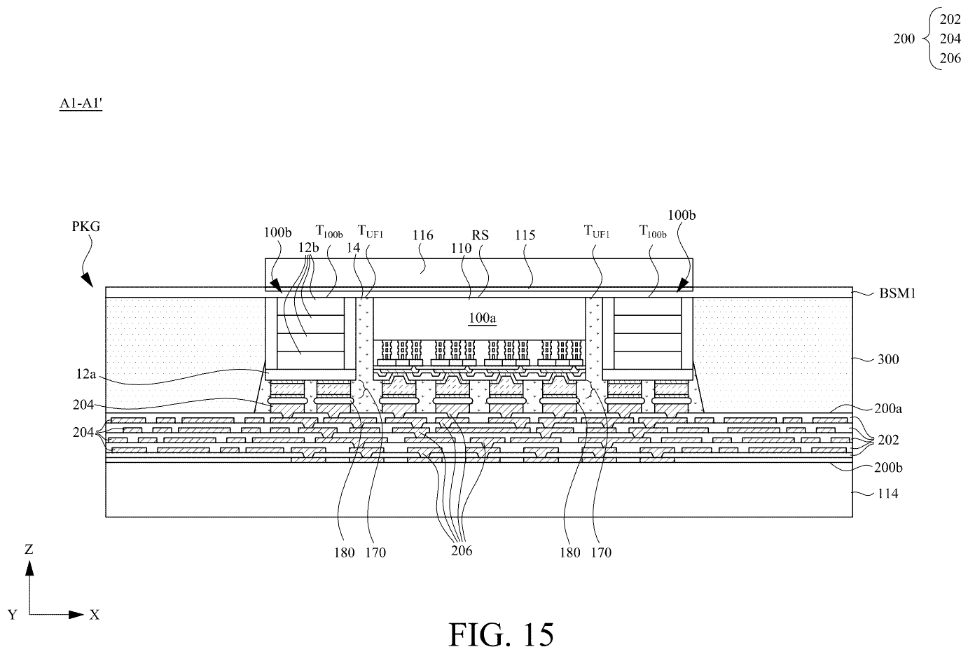

The conductive layer BSM1 can be formed to be in physical contact with the top surface T₃₀₀ of the encapsulant 300, the rear surface RS of the semiconductor substrate 110, the top surfaces T_{100b} of the semiconductor dies 100b and the top surface TUFI of the underfill layer UF1, and thus a reconstructed wafer can be thus formed. In some embodiments, The conductive layer BSM1 can include multiple metal layers, including an adhesion layer to ensure strong bond formation, a diffusion barrier layer to prevent unwanted material migration, and an anti-oxidation layer (e.g., gold) to protect against environmental damage. However, the disclosure is not limited to. In some embodiments, the material of the conductive layer BSM1 can include metal, such as aluminum (Al), titanium (Ti), nickel (Ni), vanadium (V), tantalum (Ta), silver (Ag), and gold (Au). In some embodiments, the thickness of the conductive layer BSM1 can be in a range from about 0.1 μm to about 10 μm. In some embodiments, the conductive layer BSM1 can be formed by sputtering, electroplating, deposition, or dispensing process. It is noted that the conductive layer BSM1 can be utilized to promote adhesion between the subsequently formed metallic thermal interface material (TIM) layer (e.g., TIM layer 116 as shown in FIG. 15) and the package structure, and can be changeable referred to as a backside metallization or a backside metal layer. In some alternative embodiments, there is no conductive layer BSM1 formed on the top surface T₃₀₀ of the encapsulant 300, the rear surface RS of the semiconductor substrate 110, the top surfaces T_{100b} of the semiconductor dies 100b and the top surface TUF1 of the underfill layer UF1. In some embodiments, the conductive layer BSM1 can be formed to overlap with the rear surface RS of the semiconductor substrate 110, the top surfaces T_{100b} of the semiconductor dies 100b, and the top surface TUFI of the underfill layer UF1, and non-overlap (or partially overlap) with the top surface T₃₀₀ of the encapsulant 300.

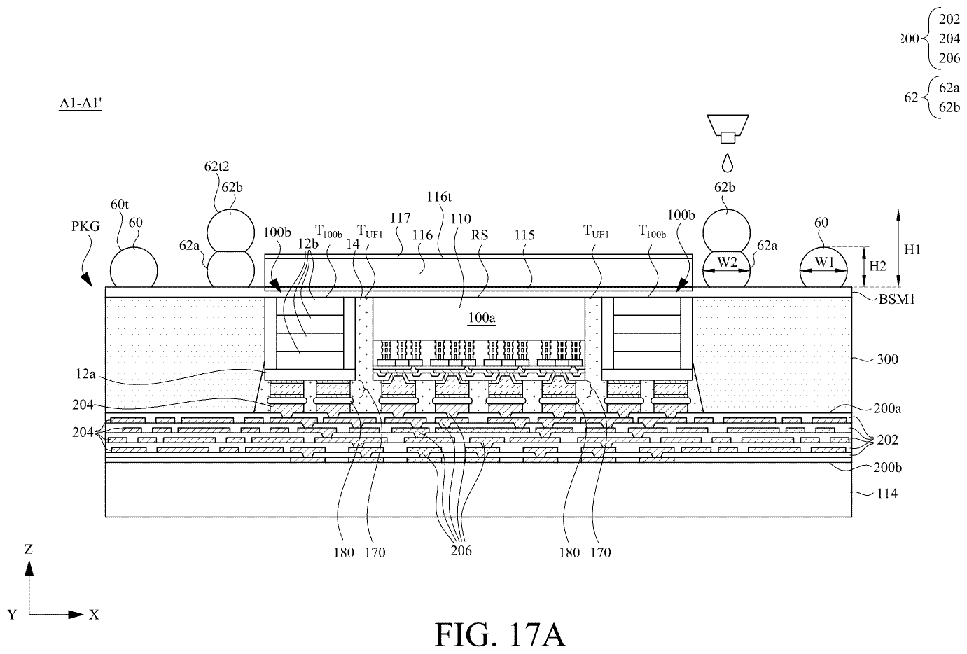

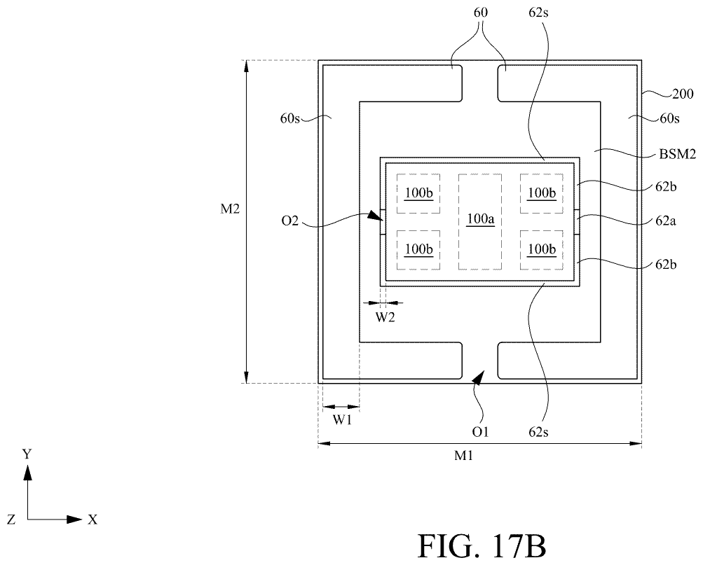

Subsequently, the reconstructed wafer can be sawed apart to form the discrete package structures PKG. In some embodiments, the package structures PKG can be a large-size full flat surface CoWoS package. A singulation process can be performed on the molding encapsulant 300 and the underfill layer UF1 to obtain the package structure PKG illustrated in FIG. 13. Although only one package structure PKG is presented in FIG. 13 for illustrative purposes, those skilled in the art can understand that after the singulation process is performed, a plurality of package structures PKG can be obtained. In some embodiments, the singulation process typically can involve dicing with a rotation blade and/or a laser beam. In other words, the singulation process can include a laser cutting process, a mechanical cutting process, a laser grooving process, other suitable processes, or a combination thereof. In some embodiments, the package structure PKG can be considered to be formed by a chip-on-wafer process, and also the package structure PKG is referred to as a chip-on-wafer package. In some embodiments, the package structures PKG can have a rectangular top view with first and second dimensions M1 and M2 (see FIG. 17B). In some embodiments, the dimension M1 can be substantially the same as the dimension M2. In some embodiments, the dimension M1 can be less or greater than the dimension M2. By way of example and not limitation, the dimension M1 can be in a range from about 50 to 150 mm, such as about 50, 55, 60, 65, 70, 75, 80, 85, 90, 91, 95, 100, 110, 120, 130, 140, or 150 mm. In some embodiments, the dimension M2 can be in a range from about 50 to 150 mm, such as about 50, 55, 60, 65, 70, 75, 80, 85, 90, 91, 95, 100, 110, 120, 130, 140, or 150 mm.

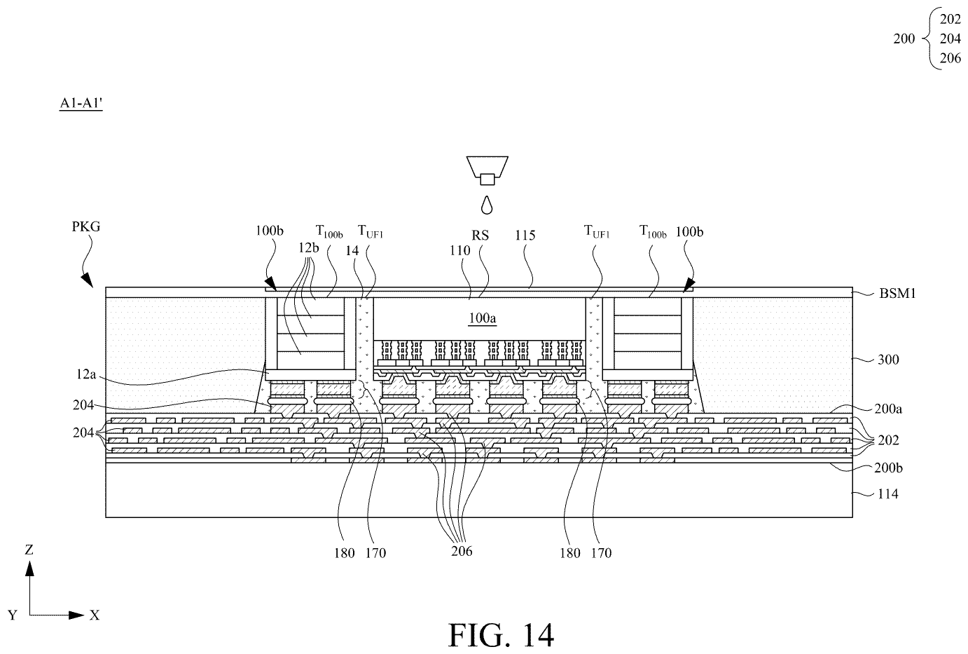

Reference is made to FIG. 14. A flux 115 may be applied onto the conductive layer BSM1 for better adhesion. For example, before the metallic TIM layer 116 (see FIG. 15) is placed on the conductive layer BSM1, the flux 115 can be formed over the package structure PKG. In some embodiments, the formation of the flux 115 can include performing a jetting process or a dispensing process. In some embodiments, the flux can be a solder flux. In some embodiments, the material of the flux 115 can include rosin or acids.

Reference is made to FIG. 15. The TIM layer 116 can be formed on the conductive layer BSM1. In some embodiments, the TIM layer 116 can be in sheet type. In some embodiments, the TIM layer 116 can be formed on the conductive layer BSM1 through a pick-and-place process. In some embodiments, the material of the TIM layer 116 can be soldered type material. In some embodiments, the TIM layer 116 can be formed by purely metallic materials and can be interchangeable referred to as a metal thermal interface material. In some embodiments, the TIM layer 116 can be free of organic material and polymeric material. In some embodiments, the material of the TIM layer 116 includes a metallic material, such as indium, copper, tin, Ag, or an alloy thereof. In some embodiments, the thermal conductivity of the TIM layer 116 ranges from about 10 W/(m·K) to about 90 W/(m·K). In some embodiments, the Young's modulus of the TIM layer 116 ranges from about 5 GPa to about 70 GPa.

In some embodiments, the TIM layer 116 can be overlapped with the semiconductor dies 100a and 100b. For example, the vertical projection of the TIM layer 116 onto the interposer 200 can be completely overlapped with the vertical projection of the semiconductor dies 100a onto the interposer 200. However, the disclosure is not limited to. In some alternative embodiments, the vertical projection of the TIM layer 116 onto the interposer 200 can be partially overlapped with the vertical projection of the semiconductor dies 100a and 100b onto the package component 20. From another point of view, the TIM layer 116 can be at least formed to be corresponded to the location of the semiconductor dies 100a and 100b.

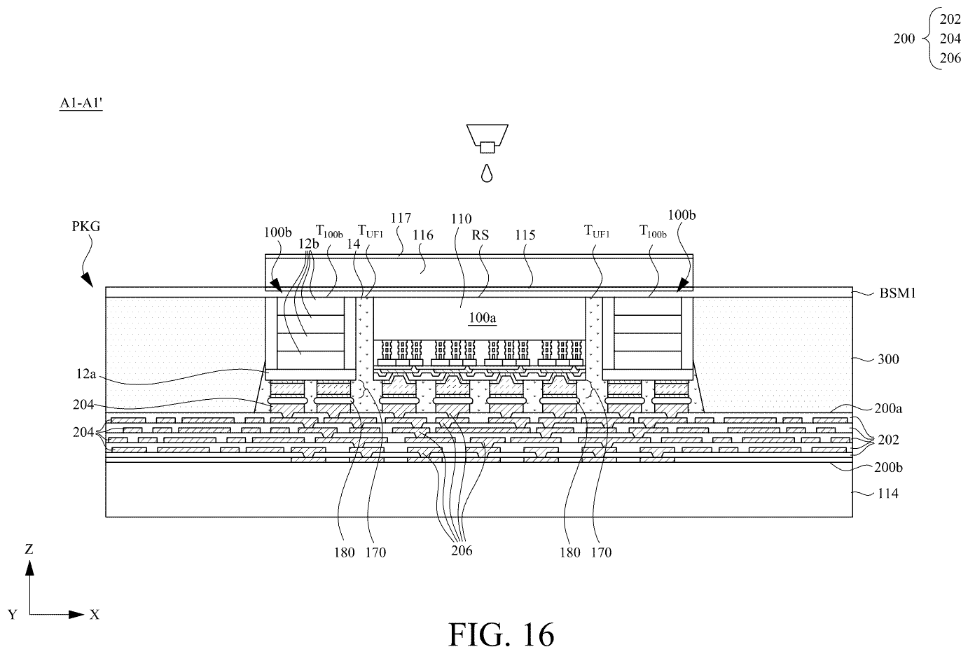

Reference is made to FIG. 16. A flux 117 may be applied onto the TIM layer 116 for better adhesion. For example, before a lid structure 70 (see FIG. 18A) is placed on the TIM layer 116, the flux 117 can be formed over the TIM layer 116. In some embodiments, the formation of the flux 117 can include performing a jetting process or a dispensing process. In some embodiments, the flux can be a solder flux. In some embodiments, the material of the flux 117 can include rosin or acids.

Reference is made to FIGS. 17A and 17B. An adhesive (ADH) structure 60 and an adhesive structure 62 can be formed over the conductive layer BSM1. Specifically, the adhesive structure 60 can be formed near edges of the package structure PKG to surround/encircle the TIM layer 116. In some embodiments, the adhesive structure 60 partially overlaps the encapsulant 300, and is physically isolated from the package structure PKG and the underfill layer UF1. In some embodiments, the adhesive structure 60 has a ring-like shape in the plane view such as the top view (see FIG. 17B) with at least one opening O1 (see FIG. 17B), thus forming separate line segments 60s. In other words, the adhesive structure 60 can have the opening O1 exposing the encapsulant 300 from the top view. The opening O1 in the adhesive structure 60 can help to accommodate thermal expansion and contraction of the materials within the package during the curing process or thermal cycling. By allowing flexibility in the adhesive structure 60, it can help to mitigate stress to prevent the adhesive structure 60 from warping or deformation that could lead to delamination or cracking. In some embodiments, the pattern of the adhesive structure 60 may be designed based on the various design. For example, the adhesive structure 60 may have a linear shape, L shape, U shape, dot shape, etc. In some embodiments, the shape of the adhesive structure 60 can depend on the shape of the package structure PKG. For example, when the package structure PKG can be in panel form (i.e., having a rectangular or squared top view), the adhesive structure 60 can exhibit a rectangular or squared ring-like shape from the top view. In some embodiments, the adhesive structure 60 can be interchangeable referred to as an adhesive layer.

The adhesive structure 62 can be formed near the TIM layer 116 to surround/encircle the TIM layer 116 and spaced apart from the adhesive structure 62. On the other hand, the adhesive structure 60 can surround/encircle the adhesive structure 62. In some embodiments, the adhesive structure 62 partially overlaps the encapsulant 300, and is physically isolated from the package structure PKG and the underfill layer UF1. In some embodiments, the adhesive structure 62 has a ring-like shape in the plane view such as the top view. In some embodiments, the adhesive structure 62 can be a layered structure having a number of layers vertical stacked with each other, and the number of layers is greater than 2, such as 2, 3, 4, or 5. By way of example and not limitation, the adhesive structure 62 can be a two-layer ring structure having a first layer 62a and a second layer 62b over and in contact with a top portion of the first layer 62a. In some embodiments, the adhesive structure 62 can have a vertical dimension H1 (e.g., height) greater than a vertical dimension H2 (e.g., height) of the adhesive structure 60. By way of example and not limitation, the vertical dimension H2 of the adhesive structure 60 can be in a range from about 0.05-0.50 mm, such as about 0.0.5, 0.10, 0.15, 0.20, 0.25, 0.30, 0.35, 0.40, 0.45, 0.50 mm, and the vertical dimension H1 of the adhesive structure 62 can be in a range from about 0.1-1.00 mm, such as about 0.10, 0.20, 0.30, 0.40, 0.50, 0.55, 0.60, 0.70, 0.80, 0.90, 1.00 mm.

In some embodiments, the adhesive structure 62 can have at least one opening thereon to prevent the distortion of the adhesive structure 62. In some embodiments, there is an opening (e.g., opening O2 as shown in FIG. 17B) at the top layer (e.g., second layer 62b) of the adhesive structure 62 in a layered stack of the adhesive structure 62 to form separate line segments 62s, and thus the adhesive structure 62 can be interchangeable referred to as an adhesive dam structure. In other words, the second layer 62b of the adhesive structure 62 can have the opening O2. The opening O2 on the top layer of adhesive structure 62 can help to accommodate thermal expansion and contraction of the materials within the package during the curing process or thermal cycling. By allowing flexibility in the adhesive structure 62, it can help to mitigate stress to prevent the adhesive structure 62 from warping or deformation that could lead to delamination or cracking. As shown in FIG. 17B, a portion of the underlying first layer 62a can be exposed form the opening O2 of the overlying second layer 62b from the top view.

On the contrary, the bottom layer (e.g., the first layer 62a) of the adhesive structure 62 being solid without any openings is to serve as a containment barrier for the TIM layer 116. During the curing process or the reflow process subsequently performed, the TIM layer 116, which is for heat dissipation from the semiconductor dies 100a/100b to the lid structure 70, can become more fluid. Without a solid barrier, the TIM layer 116 may flow out from above the semiconductor dies 100a/100b to undesired components, leading to insufficient thermal management or contamination of adjacent areas within the package. By preventing the TIM layer 116 from flowing out (or bleeding/overflowing), the first layer 62a can ensures a uniform and consistent layer of TIM layer 116 over an area between the semiconductor dies 100a/100b and the lid structure 70, ensuring maximum contact area and minimizing thermal resistance. Therefore, the top surface 62t2 (or topmost position) of the second layer 62b can have a higher elevation than the top surface 116t (or topmost position) of the TIM layer 116 and/or the top surface 60t (or topmost position) of the adhesive structure 60. In some embodiments, the first layer 62a of the adhesive structure 62 can be interchangeable referred to as a first adhesive layer, and the second layer 62b of the adhesive structure 62 can be interchangeable referred to as a second adhesive layer.

In some embodiments, the pattern of the adhesive structure 62 may be designed based on the various design. For example, the adhesive structure 62 may have a linear shape, L shape, U shape, dot shape, etc. In some embodiments, the shape of the adhesive structure 62 can depend on the shape of the package structure PKG. For example, when the package structure PKG can be in panel form (i.e., having a rectangular or squared top view), the adhesive structure 62 can exhibit a rectangular or squared ring-like shape from the top view. In some embodiment, the adhesive structure 60 has a width W1 (see FIG. 17B), the adhesive structure 62 has a width W2 (see FIG. 17B), and the width W1 can be greater than the width W2. In some embodiment, the width W1 of adhesive structure 60 is larger than width W2 of adhesive structure 62 due to their different roles. The adhesive structure 60 is located on the outer edges of the package, providing robust mechanical support and distributing stresses across a larger area, which helps maintain the package's structural integrity. The adhesive structure 62 is positioned closer to the core near the TIM layer, its narrower width suffices for containing the TIM and preventing it from spreading excessively, ensuring that it remains effective in managing heat without using unnecessary space. Thus, the width W1 can be greater than the width W2 to balance structural stability with efficient thermal management. In some embodiment, a ration of the width W1 to width W2 can be in a range from about 1.1 to 10, such as 1.1, 2, 3, 4, 5, 6, 7, 8, 9, or 10. By way of example and not limitation, the width W1 of the adhesive structure 60 can be in a range from about 2 to 15 mm, such as about 2, 3, 4, 5, 6, 7, 8, 9, 10, 11, 12, 13, 14, or 15 mm, the width W2 of the adhesive structure 62 can be in a range from about 0.5 to 5 mm, such as about 0.5, 1, 1.5, 2, 2.5, 3, 3.5, 4, 4.5, or 5 mm.

In some embodiments, the adhesive structure 60 can be applied onto the conductive layer BSM1 through a dispensing process, a spin-coating process, or the like. The adhesive structures 60 and the first layer 62a of adhesive structures 62 may be formed first, and then the second layer 62b of the adhesive structures 62 may be formed on the first layer 62a of the adhesive structures 62. In some embodiments, the adhesive structure 60/62 can have a thermal conductivity greater than about 0 W/m·K to 5 W/m·K. In some embodiments, the adhesive structure 60/62 can include an epoxy-based material. However, the disclosure is not limited to. In some alternative embodiments, other polymeric materials having adhering property may be utilized as the adhesive structure 60/62. In some embodiments, the adhesive structure 62 can be made of a same material as the adhesive structure 60. In some embodiments, the adhesive structure 62 can be made of a different material than the adhesive structure 60. In some embodiments, the first layer 62a of the adhesive structure 62 can be made of a same material as the second layer 62b of the adhesive structure 60, and thus the first and second layers 62a and 62b may form a distinguishable interface therebetween. In some embodiments, the first layer 62a of the adhesive structure 62 can be made of a different material than the second layer 62b of the adhesive structure 60, and thus the first and second layers 62a and 62b may not form a distinguishable interface therebetween.

Reference is made to FIGS. 18A-18G. A lid structure 70 can be placed over the TIM layer 116 and adhesive structures 60 and 62 such that the package structure PKG can be located between the lid structure 70 and the substrate 114. In some embodiments, the lid structure 70 can serve the function of heat dissipation. In other words, the heat generated during operation of the package structure PKG may be dissipated through the path created by the lid structure 70. In some embodiment, the lid structure 70 can be made of metal, plastic, ceramics, or the like. The metal for the lid structure 70 includes, but is not limited to, aluminum, copper, stainless steel, solder, gold, nickel, molybdenum, NiFe or NiFeCr. In some embodiments, the thermal conductivity of the lid structure 70 ranges from about 80 W/(m·K) to about 450 W/(m·K). In some embodiments, the Young's modulus of the lid structure 70 ranges from about 50 GPa to about 200 GPa.

In some embodiments, the lid structure 70 can be a flat configuration that incorporates at least one trench (e.g. trenches 70t1, 70t2) therein to include a central cover portion 70c, a leg portion 70g extending around its periphery, and a protruding portion 70p protruding from the center of the cover portion. In some embodiments, the leg portion 70g can be interchangeable referred to as a foot portion, a protruding portion, or a peripheral region, and the protruding portion can be interchangeable referred to as a central portion. In some embodiments, an extending direction of the cover portion 70c can be perpendicular to an extending direction of the leg portion 70g. From another point of view, in some embodiments, the cover portion 70c extends along the direction X and the direction Y, and the leg portion 70g extends along the direction Z. In some embodiments, the cover portion 70c and the leg portion 70g can be integrally formed. In some embodiments, the leg portion 70g can be attached to the conductive layer BSM1 through the adhesive structure 60 during the curing process. In some embodiments, the shape of the leg portion 70g can depend on the shape of the package structure PKG. For example, when the package structure PKG can be in panel form (i.e., having a rectangular or squared top view), the leg portion 70g can exhibit a rectangular or squared ring-like shape from the top view. In the other words, the footprint of the trench 70t1 can have a ring-like shape surrounding the footprint of the semiconductor dies 100a and 100b on the interposer 200 and can be interchangeable referred to as a ring-shape trench.

In some embodiments, the protruding portion 70p can protrude out from a surface of the cover portion 70c. As illustrated in FIG. 18A, the protruding portion 70p has a bottom surface at a same elevation as a bottom surface of the leg portion 70g. In some embodiments, the protruding portion 70p and the cover portion 70c can be integrally formed. For example, the material of the protruding portion 70p can be the same as the material of the cover portion 70c. However, the disclosure is not limited thereto. In some alternative embodiments, the protruding portion 70p may be installed on the cover portion 70c. For example, the material of the protruding portion 70p may be different from the material of the cover portion 70c. In some embodiments, the package structure PKG is positioned below the protruding portion 70p of the lid 70.

In some embodiments, voids may generate within the TIM layer 116 or around the lid structure 70 in semiconductor package, which in turn impacts the thermal performance of the package. These voids can be air gaps that form during the assembly process, including solder reflow, thermal interface material application, or when the package undergoes thermal cycling. In some embodiments, the voids can be generated due to outgassing of solvents or fluxes. The voids can act as thermal insulators due to the low thermal conductivity of air, reducing the overall effectiveness of heat dissipation from the semiconductor dies 100a/100b to the lid structure 70. Additionally, the voids can compromise the mechanical bond between the TIM layer 116 and the lid structure 70, reducing the structural integrity of the package and making it more susceptible to delamination or failure during thermal cycling.

Therefore, at least one trench (e.g., trenches 70t1, 70t2) can be formed on the back-side of the lid structure 70 to mitigate the impact of the voids. The trench formed on the back-side of the lid structure 70 can act as a reservoir to trap outgassing materials, flux, and air that would otherwise form voids within the interface areas. By providing the trenches 70t1 and 70t2 for the voids to escape to, the formation of voids within the TIM layer 116 or between the TIM layer 116 and the lid structure 70 can be minimized. By reducing the presence of the voids, the trenches 70t1 and 70t2 can improve thermal conductivity across the interface, resulting in more efficient heat dissipation and longer device lifespans. In some embodiments, the trenches 70t1 and 70t2 formed on the back-side of the lid structure 70 can be interchangeable referred to as cavities.

Specifically, the trench 70t1 can be defined by the leg portion 70g and the protruding portion 70p of the lid structure 70, allowing the leg portion 70g to envelop the trench 70t1 from the outside and the protruding portion 70p to envelop the trench 70t1 from the inside. In other words, the leg portion 70g, the trench 70t1, and the protruding portion 70p of the lid structure 70 create a concentric layout. The footprint of the trench 70t1 (see FIGS. 18B and 18G) can have a ring-like shape surrounding the footprint of the semiconductor dies 100a and 100b on the interposer 200. The trench 70t2 can introduce additional spatial accommodation for the adhesive structure 62 for controlling package warpage and preventing thermal interface material bleeding. The trench 70t2 (see FIGS. 18B and 18G) can have a linear shape, positioned to non-overlap with the semiconductor dies 100a and 100b. Instead, it aligns with spaces or areas (e.g., underfill layer UF1) between the semiconductor dies 100b (see FIG. 18G). In some embodiments, the trench 70t2 can be interchangeable referred to as a linear trench. In some embodiments, the footprint of the trench 70t2 is disposed within the footprint of the underfill layer UF1. As shown in FIG. 18G, the footprint of the trench 70t1 can surround the footprint of the trench 70t2 on the substrate 200. The trench 70t2 has a same depth as the trench 70t1 and communicated with the trench 70t2 (see FIGS. 18D and 18E). In some embodiments, the trench 70t2 can be aligned with the opening O2 on the adhesive structure 62. In some embodiments, the trenches 70t2 can be situated at opposite sides of the TIM layer 116.

As shown in FIG. 18B, when view from the top, the lid structure 70 can have a dimension D3 (see FIGS. 18C and 18D) in the direction X and a dimension D4 (see FIGS. 18E and 18F) in the direction Y. The protruding portion 70p can have a dimension D5 (see FIGS. 18C and 18D) in the direction X and a dimension D6 (see FIGS. 18E and 18F) in the direction Y. A pair of first portions of the leg portion 70g extending along the direction Y each can have a width W3 (see FIGS. 18C and 18D), and a pair of second portions of the leg portion 70g extending along the direction X each can have a width W4 (see FIGS. 18E and 18F). A pair of first portions of the trench 70t1 extending along the direction Y each can have a width W5 (see FIG. 18C), and a pair of second portions of the trench 70t1 extending along the direction X each can have a width W6 (see FIGS. 18E and 18F). By way of example and not limitation, the width W5 can be in a range from about 1 to 30 mm, such as about 1, 5, 10, 15, 20, 25, or 30 mm, and the width W6 can be in a range from about 1 to 30 mm, such as about 1, 5, 10, 15, 20, 25, or 30 mm. The trench 70t2 can have a width W7 (see FIG. 18F) and a length L1 (see FIG. 18D). By way of example and not limitation, the length L1 of the trench 70t2 can be in a range from about 1 to 30 mm, such as about 1, 5, 10, 15, 20, 25, or 30 mm. In some embodiments, the width W7 of the trench 70t2 can be narrower than the width W3 and/or the width W3 of the first and second portions of the trench 70t1 (see FIGS. 18C-18F). By way of example and not limitation, the width W7 can be in a range from about 0.3 to 20.0 mm, such as about 0.3, 1, 2, 4, 6, 8, 9, 12, 14, 16, 18, or 20.0 mm, and the length can be in a range from about 0.3 to 20.0 mm, such as about 0.3, 1, 2, 4, 6, 8, 9, 12, 14, 16, 18, or 20.0 mm.

As shown in FIGS. 18C-18F, the lid structure 70 can have a vertical dimension D7 (e.g., thickness). By way of example and not limitation, the vertical dimension D7 can be in a range from about 1 to 4 mm, such as about 1, 1.5, 2, 2.5, 3, 3.5, or 4 mm. The trench 70t1 can have a vertical dimension D8 (e.g., depth), and the trench 70t2 can have a vertical dimension D9 (e.g., depth). In some embodiments, the vertical dimension D9 can be the same as the vertical dimension D8. In some embodiments, the vertical dimension D9 can be different than the vertical dimension D8. By way of example and not limitation, the dimension D8 can be in a range from about 0.2 to 1.0 mm, such as about 0.2, 0.3, 0.4, 0.5, 0.6, 0.7, 0.8, 0.9, or 1.0 mm. The vertical dimension D8 can be in a range from about 0.2 to 1.0 mm, such as about 0.2, 0.3, 0.4, 0.5, 0.6, 0.7, 0.8, 0.9, or 1.0 mm.

In some embodiments, prior to the attachment of the lid structure 70, a conductive layer BSM2 can be formed on the protruding portion 70p of the lid structure 70. In some embodiments, the conductive layer BSM2 can be formed on the bottom of the trench 70t2 (see FIG. 18D). It is noted that the conductive layer BSM2 can be utilized to promote adhesion between the metallic TIM layer 116 and the lid structure 70, and can be referred to as a backside metallization or a backside metal layer. In some embodiments, the material of the conductive layer BSM2 can be the same as the material of the conductive layer BSM1. In alternative some embodiments, the material of the conductive layer BSM2 can be different from the material of the conductive layer BSM1. In some embodiments, the conductive layer BSM2 can be formed on the lid structure 70 through a plating, sputtering or dispensing process. In some embodiments, the material of the conductive layer BSM2 can include metal, such as Al, Ti, Ni, V, Au, Ag or Cu. In some embodiments, the conductive layer BSM2 can be an Au plated heat sink. That is, the back-side of the heat sink 70 can be coated with gold (Au) to improve thermal conductivity and resist oxidation. In some embodiments, the conductive layer BSM2 can be interchangeable referred to as an aurum layer.

In some embodiments, after the conductive layer BSM2 is formed on the lid structure 70, the lid structure 70 and the conductive layer BSM2 can be placed above the TIM layer 116 and the adhesive structures 60 and 62, such that the conductive layer BSM2 can be in physical contact with the top surface of the metallic TIM layer 116, the lid structure 70 can be in physical contact with the top surfaces of the adhesive structures 60 and 62. Thereafter, the nearly complete coverage of the TIM layer 116 over the package structure PKG can be achieved. As shown in FIG. 18A, the second layer 62b of the adhesive structure 62 can be situated in the first trench. In some embodiments, the first layer 62a of the adhesive structure 62 can be situated outside the trench 70t1. That is, the top surface of the first layer 62a can be at the elevation lower than the bottom surface 70b of the lid structure 70. In some embodiments, the first layer 62a of the adhesive structure 62 can have at least a portion situated in the trench 70t1. That is, the top surface of the first layer 62a can be at the elevation higher than the bottom surface 70b of the lid structure 70. In some embodiments, the top surface of the first layer 62a can be at the elevation that is the same as the bottom surface 70b of the lid structure 70.

In some embodiments, the coverage can be greater than about 95%, such as about 95, 96, 97, 98, 99, 99.5, or 99.9%. The adhesive structures 60 and 62, including their placement and the incorporation of openings (e.g., openings O1 and O2), can help manage thermal stresses and accommodates material expansion, which in turn minimizes the potential for adhesive failure or delamination by allowing the structures to flex or expand without compromising their integrity or the overall adhesion. Additionally, the incorporation of trenches (e.g., 70t1 and 70t2) in the lid structure 70 can aid in trapping outgassing materials and reducing void formation, which in turn maintains uniform contact between the TIM layer 116 and the package PKG, ensuring comprehensive coverage.

In some alternative embodiments, there is no conductive layer BSM2 formed on the lid structure 70. As shown in FIG. 18A, the TIM layer 604 can be situated between the protruding portion 70p of the lid structure 70 and the package structure PKG. The adhesive structures 60 and 62 can be situated between the leg portion 70g of the lid 70 and the encapsulant 300.

Reference is made to FIGS. 18H and 18I. FIGS. 18H and 18I illustrate schematic top views of packages corresponding to FIG. 18G in accordance with some embodiments of the present disclosure. While FIGS. 18H and 18I show embodiments with different adhesive structure configuration and different lid structure configuration than the package shown in FIGS. 1-18G, the present disclosure may repeat reference numerals and/or letters in the various examples. This repetition is for the purpose of simplicity and clarity and does not in itself dictate a relationship between the various embodiments and/or configurations discussed.

As shown in FIG. 18H, the adhesive structure 60 can include more openings O1 (e.g., four openings O1), leading to the formation of more separate line segments (60s) than the adhesive structure 60 shown in FIG. 18G. Similarly, the second layer 62b of the adhesive structure 62 can include more openings O2 (e.g., four openings O2), leading to the formation of more separate line segments 62s than the adhesive structure 62 shown in FIG. 18G. In some embodiments, more openings (e.g., opening O1 and/or O2) may facilitate a better thermal management by allowing for more uniform distribution of thermal stresses across the package structure. Additionally, more openings (e.g., opening O1 and/or O2) may introduce additional flexibility within the adhesive structure (e.g., adhesive structure 60 and/or 62), accommodating thermal expansion and contraction more effectively. This flexibility helps in reducing the risk of mechanical stress buildup, which can lead to delamination or cracking of the adhesive layers. Furthermore, more openings (e.g., opening O1 and/or O2) may allow the adhesive structure (e.g., adhesive structure 60 and/or 62) to better adapt to package warpage, maintaining effective bonding and thermal interface between the package components.

As shown in FIG. 18I, the trenches 70t2 can have a linear shape, positioned to non-overlap with the semiconductor dies 100a and 100b. The trench 70t2 can also be positioned to align with spaces (e.g., underfill layer UF1) between the semiconductor dies 100a and the semiconductor dies 100b. In some embodiments, the footprint of the trench 70t2 is disposed within the footprint of the underfill layer UF1. By capturing outgassing materials and air that could form insulating voids, this alignment of the trench 70t2 can acts as a preventive measure against the formation of thermal barrier, ensuring a more efficient thermal interface between the semiconductor dies 100a and 100b and the lid structure 70 and facilitating better heat dissipation.

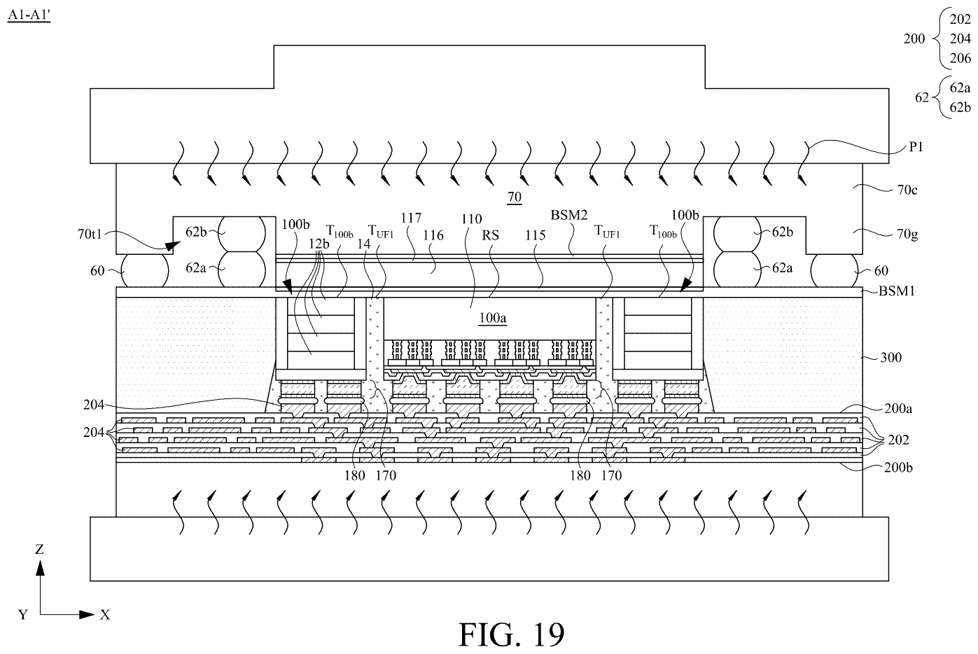

Reference is made to FIG. 19. Thereafter, the lid structure 70 and the conductive layer BSM2 are pressed against the TIM layer 116 and the adhesive structures 60 and 62. In some embodiments, pressing the lid structure 70 and the conductive layer BSM2 against the TIM layer 116 and the adhesive structures 60 and 62 can include performing a heat clamping process P1, wherein the process temperature of the heat clamping process ranges from about 60° C. to about 300° C.

Reference is made to FIGS. 20A-20E. Subsequently, a curing process P2 can be performed on the adhesive structures 60 and 62, such that the lid structure 70 can be attached to the encapsulant 300 and/or the conductive layer BSM1 through the adhesive structures 60 and 62. In detail, the curing process can be performed on the adhesive structures 60 and 62 to securely fix the lid structure 70 onto the encapsulant 300 and/or the conductive layer BSM1. In some embodiments, the process temperature of the curing process ranges from about 60° C. to about 300° C. However, the disclosure is not limited to. In some embodiments, during the curing process, the lid structure 70 can be attached to the package structure PKG through the protruding portion 70p and the TIM layer 116 attached thereto. That is to say, in such embodiments, during the curing process, there is a good physical and metallurgical connection of the lid structure 70 to the package structure PKG. In such embodiments, the process temperature of the curing process ranges from about 160° C. to about 260° C.

In some embodiments, during the curing process P2, the TIM layer 116 can be subject to flow due to the heat applied to cure it. Before the curing process P2, the TIM layer 116 can be positioned in such a way that it does not touch the adhesive structure 62. During the curing process, the heat may cause the TIM layer 116 to become more fluid, allowing it to flow and spread out. After the curing process P2, the TIM layer 116 may have flowed to come into direct contact with the adhesive structure 62. This contact can be shown in FIGS. 20C and 20D, illustrating how the TIM layer 116 expands to fill the gaps and spaces. The flow of the TIM layer during curing can be controlled to ensure that it does not overflow or extend beyond the intended boundaries, facilitated by the adhesive structure 62 which acts as a barrier to control the spread of the TIM layer 116 and maintain the integrity of the TIM layer 116.

As shown in FIGS. 20C and 20D, the adhesive structure 62 can be laterally spaced apart from an outermost one of the semiconductor dies 100a/100b by a lateral distance D2, and can be laterally spaced apart from the protruding portion 70p of the lid structure 70 by a lateral distance D10. The distance D10 between the adhesive structure 62 and the protruding portion 70p in FIG. 20C is different from the distance in FIG. 20D, primarily due to the presence of the linear trench 70t2, which extends the space between these two features in FIG. 20D. In FIG. 20C, the lateral distance D10 can represent the lateral spacing between the adhesive structure 62 and the protruding portion 70p without any intervening structures altering this path. However, in FIG. 20D, the linear trench 70t2 positioned between the adhesive structure 62 and the protruding portion 70p can increase the lateral distance. This linear trench 70t2 can effectively elongate the path, leading to a larger measurement for this distance in FIG. 20D compared to the lateral distance D10 in FIG. 20C. A ratio of the lateral distance in FIG. 20D (through the linear trench 70t2) to the lateral distance D10 in FIG. 20C can reflect how much the trench increases this separation. In some embodiments, the ratio of the lateral distance in FIG. 20D (through the trench 70t2) to the lateral distance D10 in FIG. 20C can be in a range from about 1.1 to 100, such as about 1.1, 5, 10, 15, 20, 25, 30, 35, 40, 45, 50, 55, 60, 65, 70, 75, 80, 85, 90, 95, or 100. This ratio may depend on the specific configuration and dimensions of the linear trench 70t2, allowing for flexibility in design, accommodating different thermal expansion properties and structural requirements within the package.

In some embodiments, the distance D2 can be greater than the distance D10. By way of example and not limitation, the distance D2 can be less than about 3.0 mm, such as about 0.5, 1, 1.5, 2, 2.5, or 3 mm. In some embodiments, the distance D10 can be in a range from about 0.1 to 1 mm, such as about 0.1, 0.2, 0.3, 0.4, 0.5, 0.6, 0.7, 0.8 0.9, or 1.0 mm. By way of example and not limitation, the distance D2 can be less than about 3.0 mm, such as about 0.5, 1, 1.5, 2, 2.5, or 3 mm. In some embodiments, the width W2 of the adhesive structure 62 can be less than the distance D2. In some embodiments, the width W2 of the adhesive structure 62 can be greater than the distance D10. In FIGS. 20C and 20D, the protruding portion 70p of the lid structure 70 can have a vertical dimension D11 (e.g. thickness). By way of example and not limitation, the vertical dimension D11 can be in a range from about 0.2 to 1.0 mm, such as about 0.2, 0.3, 0.4, 0.5, 0.6, 0.7, 0.8, 0.9, or 1.0 mm. As shown in FIG. 20D, there is the linear trench extension that provide extra space, it is advantageous to have the opening O2 at this location without worrying about over-thermal expansion of TIM 116 beyond the first adhesive layer 62a. In FIG. 20E, the line segments 62s of the second layer 62b of the adhesive structure 62 (see FIG. 17B) can have a maximum distance D1. By way of example and not limitation, the distance D1 can be in a range from about 0.1 to 0.5 mm, such as about 0.1, 0.2, 0.3, 0.4, or 0.5 mm.

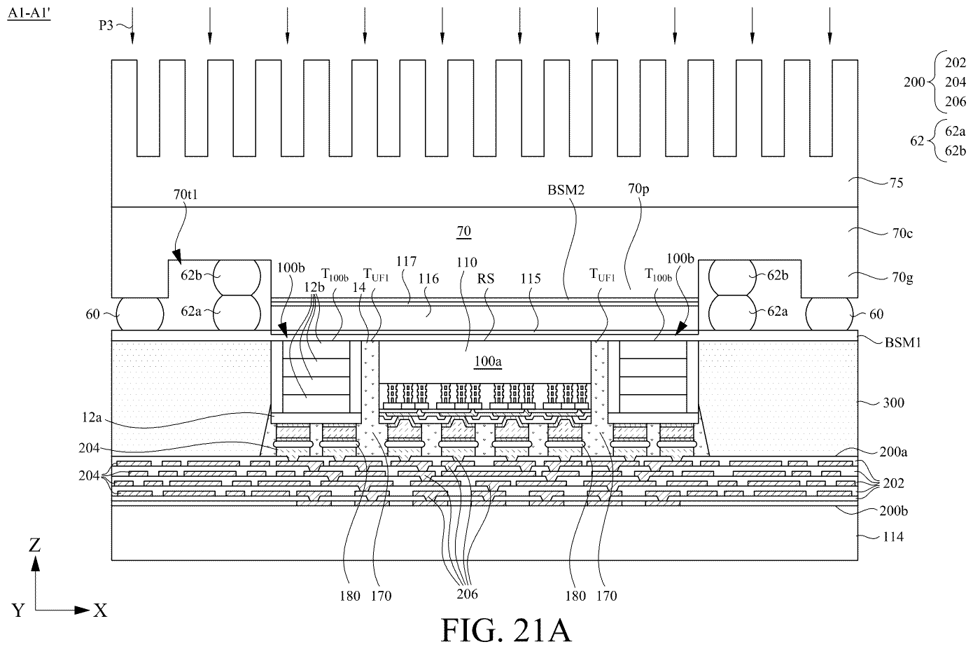

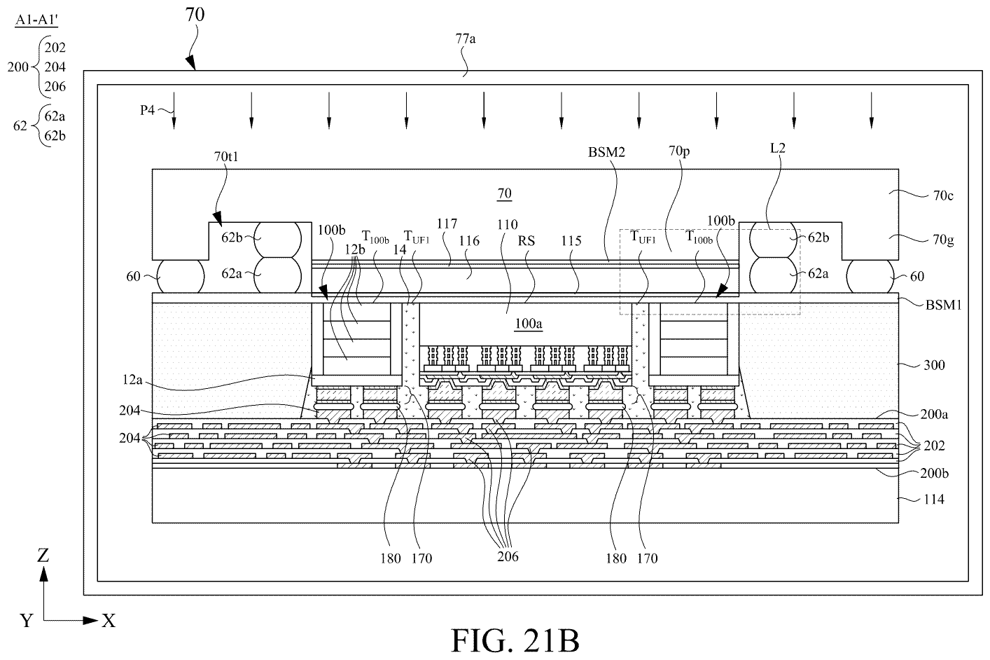

Reference is made to FIGS. 21A and 21B. An external cooling process can be performed to manage the thermal performance of a package structure PKG. This external cooling process can involve the application of cooling techniques external to the semiconductor package to enhance heat removal. The external cooling process can include a heat sink cooling process P3 (see FIG. 21A) and an immersion cooling process P4. As shown in FIG. 21A, the heat sink cooling process P3 can be performed by attaching a heat sink 75 directly to the surface of the lid structure 70. The heat sink 70 can be made of materials with high thermal conductivity, such as aluminum or copper, to maximize the surface area in contact with air. As the device operates and generates heat, this heat can be transferred from the package structure PKG to the heat sink 75 through the TIM layer 116. The heat sink 75 then can dissipate the heat into the surrounding air through natural convection or forced air flow, often aided by a fan or blower. As shown in FIG. 21B, the immersion cooling process P4 can be performed by submerging the package structure PKG in a thermally conductive but electrically insulating liquid in a tank 77a of the immersion cooling apparatus 77. This insulating cooling liquid can absorb heat from the surfaces of the package, including the lid structure 70, and then circulates away from the device, carrying the heat with it. The heated fluid can then be cooled externally, for example, by a heat exchanger, and recirculated.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a flat lid featuring a trench (or cavity) therein over a package, which in turn mitigates the delamination and prevents the formation of irregular voids associated with the use of metallic TIM between the lid and the package. This additional trench within the lid can provide the space for constructing an adhesive (ADH) dam structure. The adhesive dam structure can include more than two layers of adhesive around the chip-on-wafer (CoW) die, which in turn controls package warpage and inhibits the bleeding/overflowing of the metallic TIM between the lid and the package. Additionally, the top layer of the adhesive dam with opening can avert potential distortion of the dam itself.

In some embodiments, a method includes bonding a package component to a substrate; forming a molding compound laterally surrounding the package component; forming a thermal interface material (TIM) layer over the package component; forming a first adhesive layer over the molding compound, the first adhesive layer laterally surrounding the TIM layer; attaching a bottom surface of a lid to the TIM layer. The lid has a first trench recessed from the bottom surface of the lid, a footprint of the first trench surrounds a footprint of the package component on the substrate, and a footprint of the first adhesive layer surrounds a footprint of the first trench on the substrate. In some embodiments, a top surface of the package component is level with a top surface of the molding compound. In some embodiments, from a top view, the first adhesive layer has an opening exposing the molding compound. In some embodiments, the method further includes forming a second adhesive layer over the molding compound and laterally surrounding the TIM layer, wherein after attaching the lid, the second adhesive layer is below the first trench. In some embodiments, the method further includes forming a third adhesive layer over the second adhesive layer, wherein from a top view, the third adhesive layer has an opening exposing the second adhesive layer, and after attaching the lid, the second adhesive layer is in the first trench. In some embodiments, a top surface of the second adhesive layer is at an elevation higher than a top surface of the TIM layer. In some embodiments, the lid further comprises a second trench recessed from the bottom surface of the lid, and the footprint of the first trench surrounding a footprint of the second trench on the substrate. In some embodiments, the method further includes before attaching the lid, plating an aurum layer on the bottom surface of the lid. In some embodiments, the lid comprises copper, aluminum, steel, or combinations thereof. In some embodiments, the TIM layer comprises argentum, copper, indium, tin, or an alloy thereof.

In some embodiments, a method includes bonding a package component to a substrate; molding the package component with a molding compound; forming a thermal interfacial material (TIM) layer over the package component; forming a first adhesive layer over the molding compound and laterally surrounding the TIM layer; forming a second adhesive layer over the first adhesive layer and laterally surrounding the TIM layer; attaching a lid to the TIM layer and the second adhesive layer. In some embodiments, from a top view, the second adhesive layer has a first opening exposing the first adhesive layer. In some embodiments, from a top view, the second adhesive layer has a second opening exposing the first adhesive layer. In some embodiments, the first and second opening are situated at opposite sides of the TIM layer. In some embodiments, the method further includes before forming the TIM layer, forming a conductive layer over the package component and the molding compound, wherein the TIM layer is formed over the conductive layer.

In some embodiments, a package includes a substrate, a package component, a molding compound, a thermal interfacial material (TIM) layer, a first adhesive structure, a second first adhesive structure, and a lid. The package component is over the substrate. The molding compound laterally surrounds the package component. The TIM layer is over the package component. The first adhesive structure is over the molding compound and laterally surrounds the TIM layer. The second adhesive structure is over the molding compound and laterally surrounds the first adhesive structure, in which a height of the first adhesive structure relative to the molding compound is greater than a height of the second adhesive structure relative to the molding compound. The lid is over the TIM layer and the second adhesive layer. In some embodiments, from a top view, a width of the second adhesive structure is greater than a width of the first adhesive structure. In some embodiments, a ratio of the width of the second adhesive structure to the width of the second adhesive structure is in a range from about 5-50. In some embodiments, from a top view, the first adhesive structure has a first ring-shape profile, and the second adhesive structure has a second ring-shape profile enclosing the first ring-shape profile. In some embodiments, the package further includes before forming the TIM layer, forming a conductive layer over the package component and the molding compound, wherein the TIM layer is formed over the conductive layer.

In some embodiments, a package includes a substrate, a first semiconductor die, a second semiconductor die, a molding compound, a thermal interface material (TIM) layer, and a lid structure. The first semiconductor die over the substrate. The second semiconductor die is over the substrate. The molding compound laterally surrounds the first and second semiconductor dies. The TIM layer is over the first and second semiconductor dies. The lid structure is over the TIM layer. The lid structure has a trench, and from a top view, the trench non-overlaps with the first and second semiconductor dies and aligns with an area between the first and second semiconductor dies. In some embodiments, the lid structure comprises a ring-shape trench recessed from the bottom surface of the lid, and a footprint of the ring-shape trench surrounds a footprint of the first and second semiconductor dies on the substrate. In some embodiments, the trench is spatially communicated with the ring-shape trench. In some embodiments, the package further includes a first ring-shape adhesive layer over the molding compound and surrounding the TIM layer, and a second ring-shape adhesive layer over the first ring-shape adhesive layer. In some embodiments, from the top view, the second ring-shape adhesive layer has an opening exposing the first ring-shape adhesive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
bonding a package component to a substrate;
forming a molding compound laterally surrounding the package component;
forming a thermal interface material (TIM) layer over the package component;
forming a first adhesive layer over the molding compound, the first adhesive layer laterally surrounding the TIM layer; and
attaching a bottom surface of a lid to the TIM layer, wherein the lid has a first trench recessed from the bottom surface of the lid, a footprint of the first trench surrounds a footprint of the package component on the substrate, and a footprint of the first adhesive layer surrounds a footprint of the first trench on the substrate.

2. The method of claim 1, wherein a top surface of the package component is level with a top surface of the molding compound.

3. The method of claim 1, wherein from a top view, the first adhesive layer has an opening exposing the molding compound.

4. The method of claim 1, further comprising:
forming a second adhesive layer over the molding compound and laterally surrounding the TIM layer, wherein after attaching the lid, the second adhesive layer is below the first trench.

5. The method of claim 4, further comprising:
forming a third adhesive layer over the second adhesive layer, wherein from a top view, the third adhesive layer has an opening exposing the second adhesive layer, and after attaching the lid, the second adhesive layer is in the first trench.

6. The method of claim 4, wherein a top surface of the second adhesive layer is at an elevation higher than a top surface of the TIM layer.

7. The method of claim 1, wherein the lid further comprises a second trench recessed from the bottom surface of the lid, and the footprint of the first trench surrounds a footprint of the second trench on the substrate.

8. The method of claim 1, further comprising:
before attaching the lid, plating an aurum layer on the bottom surface of the lid.

9. The method of claim 1, wherein the lid comprises copper, aluminum, steel, or combinations thereof.

10. The method of claim 1, wherein the TIM layer comprises argentum, copper, indium, tin, or an alloy thereof.

11. A package, comprising:
a substrate;
a package component over the substrate;
a molding compound laterally surrounding the package component;
a thermal interfacial material (TIM) layer over the package component;
a first adhesive structure over the molding compound and laterally surrounding the TIM layer;
a second adhesive structure over the molding compound and laterally surrounding the first adhesive structure, wherein a height of the first adhesive structure relative to the molding compound is greater than a height of the second adhesive structure relative to the molding compound; and
a lid over the TIM layer and the second adhesive structure.

12. The package of claim 11, wherein from a top view, a width of the second adhesive structure is greater than a width of the first adhesive structure.

13. The package of claim 12, wherein a ratio of the width of the second adhesive structure to the width of the second adhesive structure is in a range from about 5-50.

14. The package of claim 11, wherein from a top view, the first adhesive structure has a first ring-shape profile, and the second adhesive structure has a second ring-shape profile enclosing the first ring-shape profile.

15. The package of claim 11, further comprising:
before forming the TIM layer, forming a conductive layer over the package component and the molding compound, wherein the TIM layer is formed over the conductive layer.

16. A package, comprising:
a substrate;
a first semiconductor die over the substrate;
a second semiconductor die over the substrate;
a molding compound laterally surrounding the first and second semiconductor dies;
a thermal interface material (TIM) layer over the first and second semiconductor dies; and
a lid structure over the TIM layer, wherein the lid structure has a trench, and from a top view, the trench non-overlaps with the first and second semiconductor dies and aligns with an area between the first and second semiconductor dies.

17. The package, of claim 16, wherein the lid structure comprises a ring-shape trench recessed from a bottom surface of the lid structure, and a footprint of the ring-shape trench surrounds a footprint of the first and second semiconductor dies on the substrate.

18. The package, of claim 17, wherein the trench is spatially communicated with the ring-shape trench.

19. The package of claim 16, further comprising
a first ring-shape adhesive layer over the molding compound and surrounding the TIM layer; and
a second ring-shape adhesive layer over the first ring-shape adhesive layer.

20. The package of claim 19, wherein from the top view, the second ring-shape adhesive layer has an opening exposing the first ring-shape adhesive layer.
